(19) United States
(12) Patent Application Publication
(10) Pub. No.: US 2012/0286275 A1
(43) Pub. Date: Nov. 15, 2012

(54) DISPLAY DEVICE AND ELECTRONIC APPARATUS

(75) Inventors: Satoshi Tatara, Kanagawa (JP); Katsuhide Uchino, Kanagawa (JP)

(73) Assignee: SONY CORPORATION, Tokyo (JP)

(21) Appl. No.: 13/442,372

(22) Filed: Apr. 9, 2012

(30) Foreign Application Priority Data
May 10, 2011 (JP) 2011-105285

(51) Int. Cl. H01L 33/08

(52) U.S. Cl. 257/59; 257/71; 257/E33.053

(57) ABSTRACT

A display device has pixels including electro-optical elements and transistors. Each pixel has a metal layer of a gate electrode of the transistor, a semiconductor layer in which a source region and a drain region of the transistor are formed, and a capacitance element formed between the same metal layer as the metal layer of the gate electrode and the semiconductor layer upon application of a voltage to the metal layer.

### CROSS REFERENCES TO RELATED APPLICATIONS

The present application claims priority to Japanese Priority Patent Application JP 2011-105285 filed in the Japan Patent Office on May 10, 2011, the entire content of which is hereby incorporated by reference.

### BACKGROUND

The present disclosure relates to display devices and electronic apparatuses. In particular, the present disclosure relates to a flat-panel (a flat) display device in which pixels including electro-optical elements are arranged in a matrix and to an electronic apparatus having the display device.

As flat-panel display devices, organic EL (electroluminescent) display devices, LCD (liquid crystal display) devices, and PDP (plasma display panel) devices are widely available.

In such display devices, pixels (pixel circuits) including electro-optical elements and transistors are arranged in a matrix on a substrate (panel). In addition to the electro-optical elements and the transistors, the pixels in the display device, for example, the pixels in the organic EL display devices may include capacitance elements, such as storage capacitors and auxiliary capacitors (see, for example, Japanese Unexamined Patent Application Publication No. 2008-51990).

### SUMMARY

Display devices in which pixels including the capacitance elements are arranged, for example, the organic EL display device disclosed in Japanese Unexamined Patent Application Publication No. 2008-51990, typically employ a configuration in which an insulating film between opposing metal layers is used as a dielectric to form a capacitance element therebetween. If the capacitance element to be fabricated in the pixel can be formed in a region other than the region between those metal layers, the degree of freedom of the cross-sectional structure of the pixel can be improved.

Accordingly, it is desirable to provide a display device in which a capacitance element to be fabricated in a pixel is formed in a region other than the region between metal layers, thereby making it possible to improve the degree of freedom of a cross-sectional structure of the pixel, and also to provide an electronic apparatus having the display device.

According to an embodiment of the present disclosure, there is provided a display device having pixels including electro-optical elements and transistors. Each pixel has a metal layer of a gate electrode of the transistor, a semiconductor layer in which a source region and a drain region of the transistor are formed, and a capacitance element formed between the same metal layer as the metal layer of the gate electrode and the semiconductor layer upon application of a voltage to the metal layer. The display device may be used as display devices in various electronic apparatuses.

When a high voltage relative to the voltage at the semiconductor layer is applied to the metal layer in a structure in which the same metal layer as that metal layer of the gate electrode of the transistor and the semiconductor layer in which the source region and the drain region of the transistor are formed, a channel is formed at a surface of the semiconductor layer and a capacitor is formed using a gate insulating film as a dielectric. That is, upon application of a voltage to the metal layer, a channel is formed at a surface of the semiconductor layer, and a capacitor is formed using a gate insulating between the metal layer and the semiconductor layer. The use of the capacitor as a capacitance element to be fabricated into the pixel allows the capacitance element to be formed in a region other than the region between the metal layers.

According to the present disclosure, since the capacitance element to be fabricated in the pixel can be formed in a region other than the region between the metal layers, the degree of freedom of the cross-sectional structure of the pixel can be improved.

Additional features and advantages are described herein, and will be apparent from the following Detailed Description and the figures.

### BRIEF DESCRIPTION OF THE FIGURES

FIG. 1 is a system block diagram illustrating an overview of a basic configuration of an active matrix organic EL display device to which an embodiment of the present disclosure is applied;

FIG. 2 is a circuit diagram illustrating one example of a specific circuit configuration of one pixel (pixel circuit);

FIG. 3 is a timing waveform diagram illustrating a basic circuit operation of the organic EL display device to which the embodiment of the present disclosure is applied;

FIGS. 4A to 4D are diagrams (part 1) illustrating the basic circuit operation of the organic EL display device to which the embodiment of the present disclosure is applied;

FIGS. 5A to 5D are diagrams (part 2) illustrating the basic circuit operation of the organic EL display device to which the embodiment of the present disclosure is applied;

FIG. 6A is a graph illustrating a problem due to variations in a threshold voltage of a drive transistor and FIG. 6B is a graph illustrating a problem due to variations in mobility of the drive transistor;

FIG. 7 is a cross sectional view illustrating a cross-sectional structure of a transistor having a top gate structure;

FIGS. 8A to 8C illustrate a why a voltage is applied to a metal layer to form a capacitance element between the metal layer and a semiconductor layer;

FIG. 9 is a cross-sectional view illustrating a cross-sectional structure of a pixel according to the embodiment of the present disclosure;

FIG. 10 is a circuit diagram of a pixel circuit according to a first embodiment;

FIG. 11 illustrates a layout example of a panel for externally applying a constant voltage to a second electrode of an auxiliary capacitor;

FIG. 12 is a timing waveform diagram illustrating a mechanism in which the luminance decreases when the potential of the metal layer decreases relative to the potential of the semiconductor layer;

FIG. 13 illustrates a capacitance characteristic of the semiconductor capacitance;

FIG. 14 is a timing waveform diagram illustrating a mechanism in which variations in the operating points of organic EL elements in the pixels cause luminance non-uniformity;

FIG. 15 is a timing waveform diagram illustrating a second embodiment;

FIG. 16 is a timing waveform diagram illustrating exemplary drive timings according to the second embodiment;

FIG. 17 is a system block diagram illustrating an example of a panel configuration for realizing the exemplary drive timings according to the second embodiment;

FIG. 18 is a circuit diagram of a pixel circuit according to a modification of the second embodiment;

FIG. 19 is a perspective view illustrating the external appearance of a television set to which the embodiment of the present disclosure is applied;

FIGS. 20A and 20B are a front perspective view and a rear perspective view, respectively, illustrating the external appearance of a digital camera to which the embodiment of the present disclosure is applied;

FIG. 21 is a perspective view illustrating the external appearance of a notebook personal computer to which the embodiment of the present disclosure is applied;

FIG. 22 is a perspective view illustrating the external appearance of a video camera to which the embodiment of the present disclosure is applied; and

FIGS. 23A to 23G are external views of a mobile phone to which the embodiment of the present disclosure is applied, FIG. 23A being a front view of the mobile phone when it is opened, FIG. 23B being a side view thereof, FIG. 23C being a front view when the mobile phone is closed, FIG. 23D being a left side view, FIG. 23E being a right side view, FIG. 23F being a top view, and FIG. 23G being a bottom view.

### DETAILED DESCRIPTION

Modes (hereinafter referred to as “embodiments”) for realizing the technology according to the present disclosure will be described below in detail with reference to the accompanying drawings. A description below is given in the following sequence:

1. Organic EL Display Device to which Embodiment of Present Disclosure is Applied
1-1. System Configuration
1-2. Basic Circuit Operation
1-3. Bottom Gate Structure and Top Gate Structure

2. Embodiments
2-1. First Embodiment
2-2. Second Embodiment

3. Application Examples

4. Electronic Apparatuses

### 1. ORGANIC EL DISPLAY DEVICE TO WHICH EMBODIMENT OF PRESENT DISCLOSURE IS APPLIED

### 1-1. System Configuration

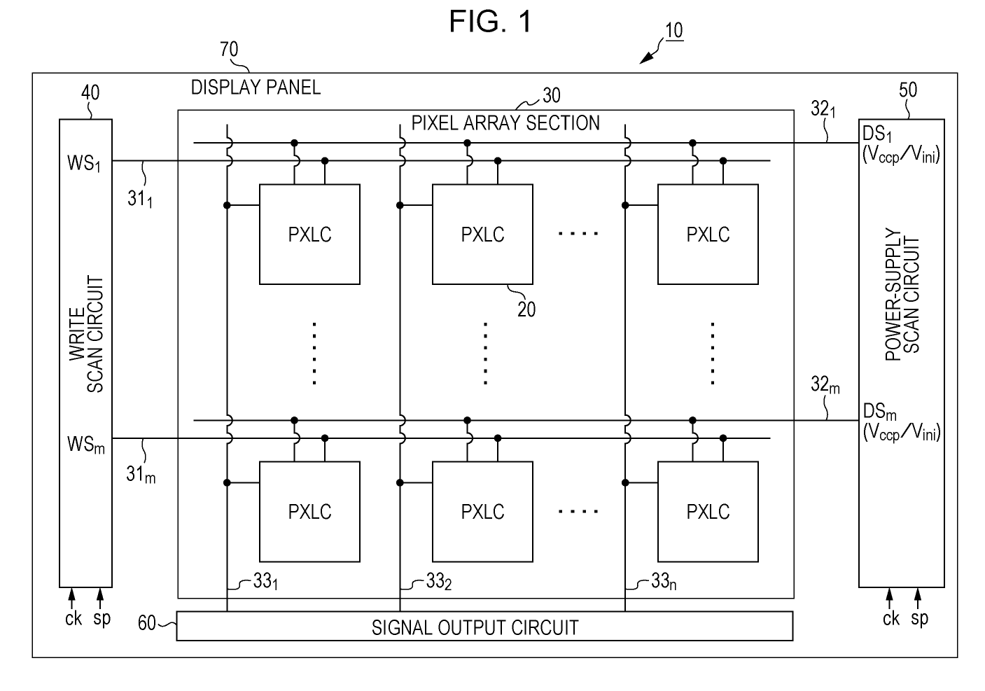

FIG. 1 is a system block diagram illustrating an overview of a basic configuration of an active matrix display device to which an embodiment of the present disclosure is applied.

In the active matrix organic display device, active elements (e.g., insulated-gate field effect transistors) provided in the same pixels as the pixels in which the electro-optical elements are provided control current flowing in the organic EL elements. The insulated-gate field effect transistors are typically implemented by TFTs (thin film transistors).

A description will be given of an example of an active matrix organic EL display device in which a current-driven electro-optical element (e.g., an organic EL element) having a light-emission luminance that varies according to the value of current flowing through the device is used as a light-emitting element of a pixel (a pixel circuit).

As illustrated in FIG. 1, an organic EL display device 10 according to the present application example has pixels 20 including organic EL elements, a pixel array section 30 in which the pixels 20 are two-dimensionally arranged in a matrix, and a drive circuit section disposed in the vicinity of the pixel array section 30. The drive circuit section includes a write scan circuit 40, a power-supply scan circuit 50, a signal output circuit 60, and so on to drive the pixels 20 in the pixel array section 30.

When the organic EL display device 10 is a color display device, a single pixel (a unit pixel) that serves as a unit for forming a color image is constituted by multiple sub pixels, which correspond to the pixel 20 illustrated in FIG. 1. More specifically, in the color display device, one pixel is constituted by three sub pixels, for example, a sub pixel for emitting red (R) light, a sub pixel for emitting green (G) light, and a sub pixel for emitting blue (B) light.

One pixel, however, is not limited to a combination of sub pixels having the three primary colors including RGB. That is, a sub pixel for another color or sub pixels for other colors may be further added to the three-primary-color sub pixels to constitute a single pixel. More specifically, for example, in order to improve the luminance, a sub pixel for emitting white (W) light may be added to constitute a single pixel or, in order to increase the color reproduction range, at least one sub pixel for emitting complementary color may be added to constitute a single pixel.

With respect to the pixels 20 arranged in m rows×n columns in the pixel array section 30, scan lines 31 (31₁ to 31ₘ) and power-supply lines 32 (32₁ to 32ₘ) are arranged in corresponding pixel rows along a row direction (i.e., in a direction in which the pixels 20 in the pixel rows are arranged). In addition, with respect to the pixels 20 arranged in m rows×n columns, signal lines 33 (33₁ to 33ₙ) are arranged in corresponding pixel columns along a column direction (i.e., in a direction in which the pixels 20 in the pixel columns are arranged).

The scan lines 31₁ to 31ₘ are connected to corresponding row output ends of the write scan circuit 40. The power-supply lines 32₁ to 32ₘ are connected to corresponding row output ends of the power-supply scan circuit 50. The signal lines 33₁ to 33ₙ are connected to corresponding column output ends of the signal output circuit 60.

In general, the pixel array section 30 is provided on a transparent insulating substrate, such as a glass substrate. Thus, the organic EL display device 10 has a flat panel structure. Drive circuits for the pixels 20 in the pixel array section 30 may be fabricated using amorphous silicon TFTs or low-temperature polysilicon TFTs. When low-temperature polysilicon TFTs are used, the write scan circuit 40, the power-supply scan circuit 50, and the signal output circuit 60 may also be disposed on the display panel (plate) 70 included in the pixel array section 30, as illustrated in FIG. 1.

The write scan circuit 40 includes shift register circuits or the like that sequentially shift (transfer) a start pulse sp in synchronization with a clock pulse ck. During signal-voltage writing of a video signal to the pixels 20 in the pixel array section 30, the write scan circuit 40 sequentially supplies write scan signals WS (WS₁ to WSₘ) to the corresponding scan lines 31 (31₁ to 31ₘ) to thereby sequentially scan the pixels 20 in the pixel array section 30 row by row (i.e., line sequence scanning).

The power-supply scan circuit 50 includes shift register circuits or the like that sequentially shift a start pulse sp in synchronization with a clock pulse ck. In synchronization with line sequential scanning performed by the write scan circuit 40, the power-supply scan circuit 50 supplies power-supply potentials DS (DS₁ to DSₘ) to the corresponding power-supply lines 32 (32₁ to 32ₘ). Each power-supply potential DS can be switched between a first power-supply potential V_{ccp} and a second power-supply potential Vᵢₙᵢ, which is lower than the first power-supply potential V_{ccp}. Through the switching between the power supply potentials V_{ccp} and Vᵢₙᵢ of the power-supply potential DS, light emission and light non-emission of the pixels 20 are controlled.

The signal output circuit 60 selectively outputs a signal voltage V_{sig} of a video signal corresponding to luminance information supplied from a signal supply source (not illustrated) and a reference voltage V_{ofs}. The reference voltage V_{ofs} serves as a reference potential for the signal voltage V_{sig} of the video signal (and corresponds to, for example, a voltage for a black level of a video signal) and is used for threshold correction processing (described below).

The signal voltage V_{sig} and the reference potential V_{ofs} selectively output from the signal output circuit 60 are written, for each pixel row selected by the scanning of the write scan circuit 40, to the corresponding pixels 20 in the pixel array section 30 through the signal lines 33 (33₁ to 33ₙ). That is, the signal output circuit 60 has a line-sequential writing drive system for writing the signal voltage V_{sig} row by row (or line by line).

### (Pixel Circuit)

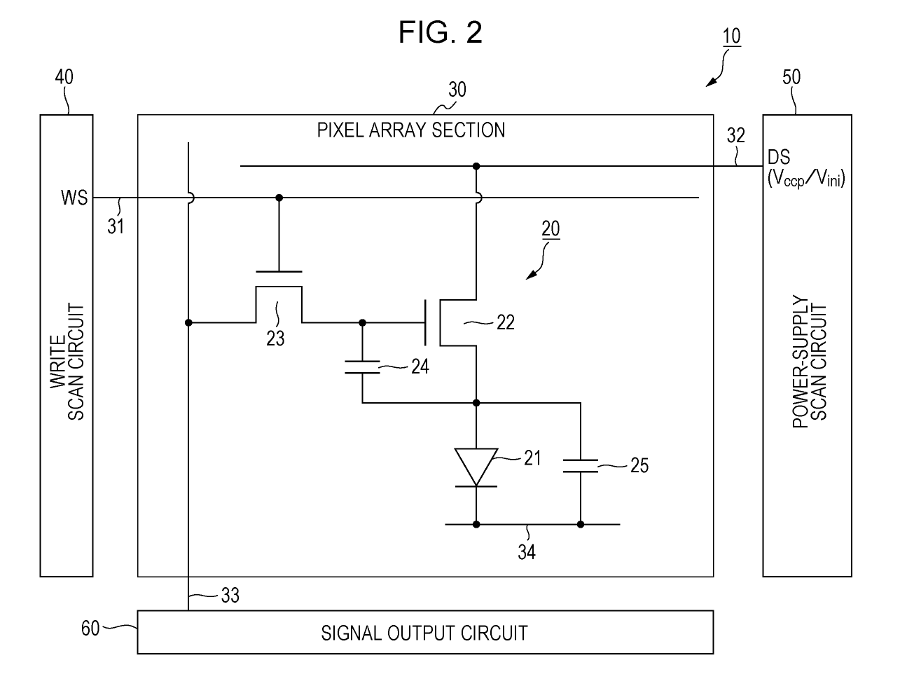

FIG. 2 is a circuit diagram illustrating one example of a specific circuit configuration of one pixel (pixel circuit) 20. The pixel 20 has a light emitting section including an organic EL element 21, which is a current-driven electro-optical element. The organic EL element 21 has a light-emission luminance that changes in accordance with the value of current flowing through the device.

As illustrated in FIG. 2, in addition to the organic EL element 21, the pixel 20 includes a drive circuit for driving the organic EL element 21 by flowing current to the organic EL element 21. The organic EL element 21 has a cathode electrode connected to a common power-supply line 34 that is connected to all pixels 20 (this connection may be referred to as “common wiring”).

The drive circuit for driving the organic EL element 21 has a drive transistor 22, a write transistor 23, a storage capacitor 24, and an auxiliary capacitor 25. The drive transistor 22 and the write transistor 23 may be implemented by n-channel TFTs. However, the illustrated combination of conductivity types of the drive transistor 22 and the write transistor 23 is merely one example, and the combination of conductivity types is not limed thereto. In addition, the relationship of wiring connections of the transistors, the storage capacitor, the organic EL device, and so on is not limited to the disclosed relationship.

A first electrode (a source/drain electrode) of the drive transistor 22 is connected to an anode electrode of the organic EL element 21 and a second electrode (a source/drain electrode) of the drive transistor 22 is connected to a corresponding one of the power-supply lines 32 (32₁ to 32ₘ).

A first electrode (a source/drain electrode) of the write transistor 23 is connected to a corresponding one of the signal lines 33 (33₁ to 33ₙ) and a second electrode (a source/drain electrode) of the write transistor 23 is connected to a gate electrode of the drive transistor 22. A gate electrode of the write transistor 23 is connected to a corresponding one of the scan lines 31 (31₁ to 31ₘ).

The expression “first electrodes” of the drive transistor 22 and the write transistor 23 refer to metal wiring lines electrically connected to the source/drain regions and the expression “second electrodes” refer to metal wiring lines electrically connected to the drain/source regions. Depending upon a potential relationship between the first electrode and the second electrode, the first electrode acts as a source electrode or a drain electrode or the second electrode also acts as a drain electrode or a source electrode.

A first electrode of the storage capacitor 24 is connected to the gate electrode of the drive transistor 22 and a second electrode of the storage capacitor 24 is connected to the first electrode of the drive transistor 22 and the anode electrode of the organic EL element 21.

A first electrode of the auxiliary capacitor 25 is connected to the anode electrode of the organic EL element 21 and a second electrode of the auxiliary capacitor 25 is connected to the common power-supply line 34. The auxiliary capacitor 25 serves as an auxiliary of an equivalent capacitance of the organic EL element 21 in order to compensate for a shortage of the equipment capacitance for the organic EL element 21 and in order to increase the write gain of the video signals with respect to the storage capacitor 24.

In this case, although the second electrode of the auxiliary capacitor 25 is connected to the common power-supply line 34, the second electrode of the auxiliary capacitor 25 may be connected to a node at a fixed potential, instead of the common power-supply line 34. Connection of the second electrode of the auxiliary capacitor 25 to a node at a fixed potential makes it possible to compensate for a shortage of the capacitance for the organic EL element 21 and also makes it possible to achieve an increase in the write gain of the video signal with respect to the storage capacitor 24.

The write transistor 23 in the pixel 20 having the above-described configuration enters a conductive state in response to a high (i.e., active) write scan signal WS supplied from the write scan circuit 40 to the gate electrode of the write transistor 23 through the scan line 31. The write transistor 23 then samples the signal voltage V_{sig} of the video signal (corresponding to the luminance information) or the reference potential V_{ofs} supplied from the signal output circuit 60 through the signal line 33 and writes the sampled signal voltage V_{sig} or the reference voltage V_{ofs} to the pixel 20. The written signal voltage V_{sig} or reference voltage V_{ofs} is applied to the gate electrode of the drive transistor 22 and is also stored by the storage capacitor 24.

When the power-supply potential DS of the corresponding one of the power-supply lines 32 (32₁ to 32ₘ) is the first power-supply potential V_{ccp}, the drive transistor 22 operates in a saturation region with its first electrode acting as a drain electrode and its second electrode acting as a source electrode. Thus, in response to the current supplied from the power-supply line 32, the drive transistor 22 drives the light emission of the organic EL element 21 by supplying drive current thereto. More specifically, by operating in the saturation region, the drive transistor 22 supplies, to the organic EL element 21, drive current having a current value corresponding to the voltage value of the signal voltage V_{sig} stored by the storage capacitor 24. The drive current causes the organic EL element 21 to be driven to emit light.

When the power-supply potential DS is switched from the first power-supply potential V_{ccp} to the second power-supply potential Vᵢₙᵢ, the drive transistor 22 operates as a switching transistor with its first electrode acting as a source electrode and its second electrode acting as a drain electrode. Through the switching operation, the drive transistor 22 stops the supply of the drive current to the organic EL element 21 to put the organic EL element 21 into a light non-emission state. That is, the drive transistor 22 also has the function of a transistor for controlling the light emission and non-emission of the organic EL element 21.

The drive transistor 22 performs a switching operation to provide a period (a light non-emission period) in which the organic EL element 21 does not emit light, thus making it possible to control the (duty) ratio of the light emission period and the light non-emission period of the organic EL element 21. Through the duty control, afterimage involved in the light emission of the pixel 20 throughout one display frame period can be reduced. Thus, in particular, the image quality of a moving image can be further improved.

Of the first and second power-supply voltages V_{ccp} and Vᵢₙᵢ selectively supplied from the power-supply scan circuit 50 through the power-supply line 32, the first power-supply potential V_{ccp} is a power-supply potential for supplying, to the drive transistor 22, drive current for driving the light emission of the organic EL element 21. The second power-supply potential Vᵢₙᵢ is a power-supply potential for reversely biasing the organic EL element 21. The second power-supply potential Vᵢₙᵢ is set lower than the reference voltage V_{ofs}. For example, the second power-supply potential Vᵢₙᵢ is set to a potential that is lower than V_{ofs}−Vₜₕ, preferably, to a potential that is sufficiently lower than V_{ofs}−Vₜₕ, where Vₜₕ indicates a threshold voltage of the drive transistor 22.

### 1-2. Basic Circuit Operation

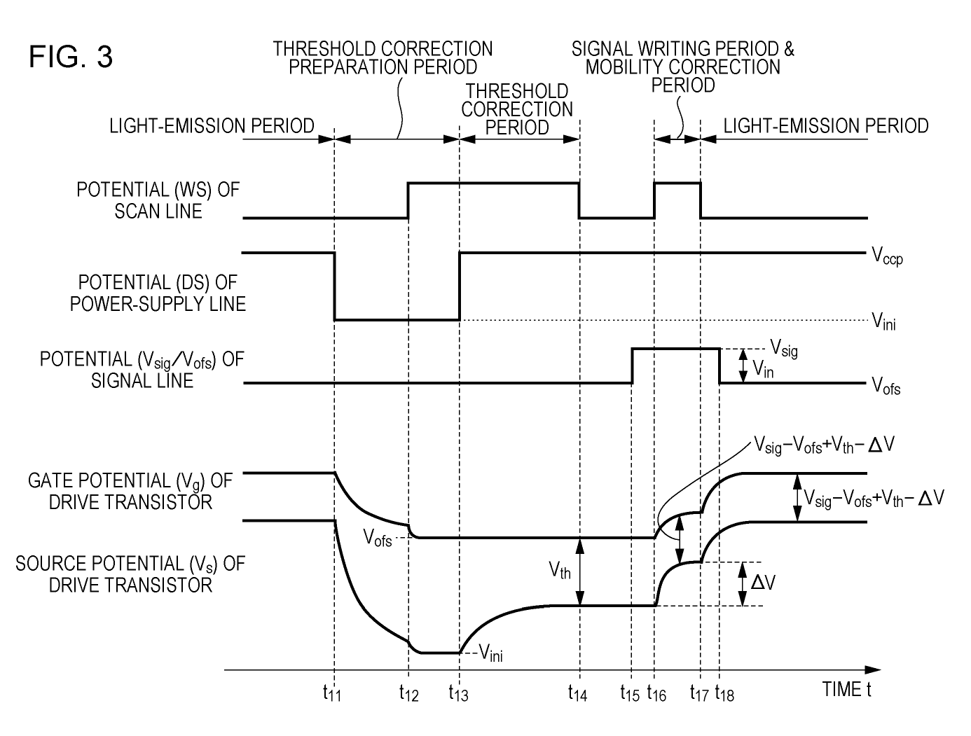

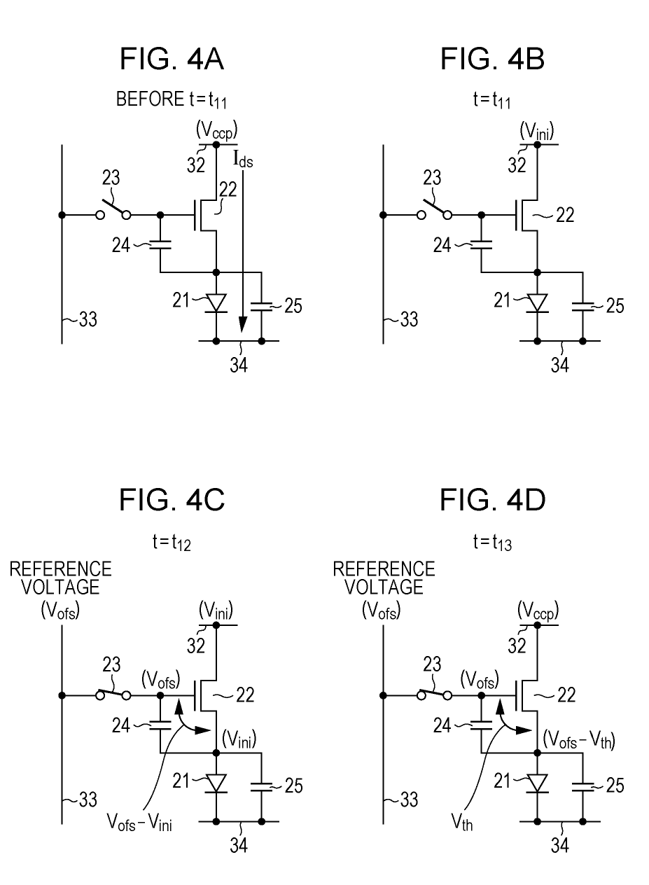

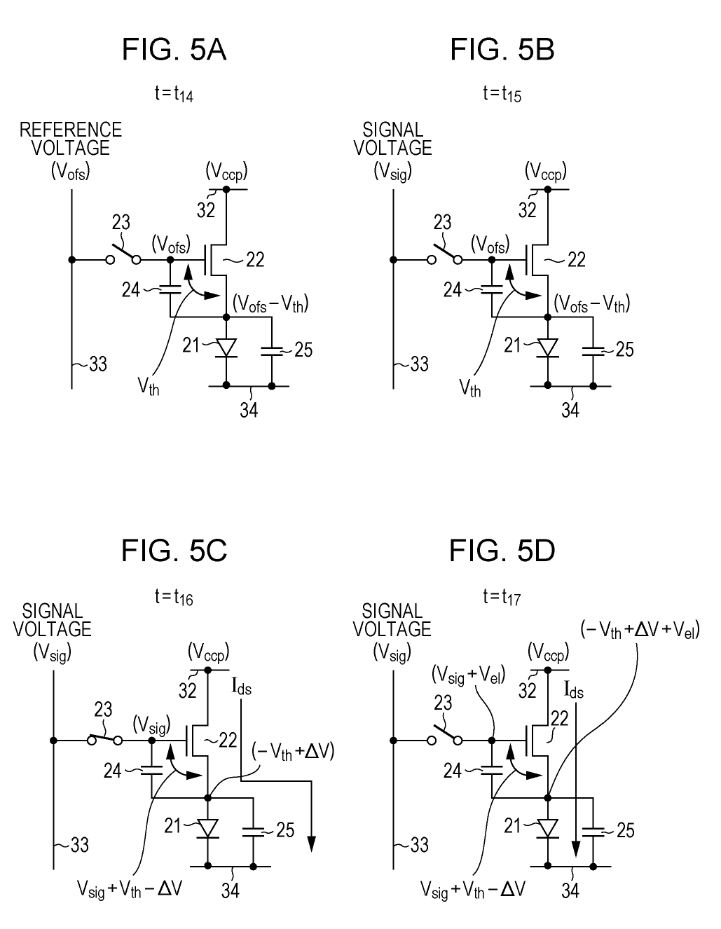

Next, a basic circuit operation of the organic EL display device 10 having the above-described configuration will be described with reference to a timing waveform diagram illustrated in FIG. 3 and operation diagrams illustrated in FIGS. 4A to 5D. In the operation diagrams illustrated in FIGS. 4A to 5D, the write transistor 23 is represented by a switch symbol, for simplicity of illustration.

The timing waveform diagram of FIG. 3 illustrates a change in the potential (write scan signal) WS of the scan line 31, a change in the potential (power-supply potential) DS of the power-supply line 32, a change in the potential (V_{sig}/V_{ofs}) of the signal line 33, and changes in a gate potential V_{g} and a source potential Vₛ of the drive transistor 22.

### (Light Emission Period of Previous Display Frame)

In the timing waveform diagram of FIG. 3, a period before time t₁₁ is a light emission period of the organic EL element 21 for a previous display frame. In the light emission period for the previous display frame, the potential DS of the power-supply line 32 is at the first power-supply potential (hereinafter referred to as a “high potential”) V_{ccp} and the write transistor 23 is in the non-conductive state.

The drive transistor 22 is designed so that, at this point, it operates in its saturation region. Thus, as illustrated in FIG. 4A, a drive current (a drain-source current) I_{ds} corresponding to a gate-source voltage V_{gs} of the drive transistor 22 is supplied from the power-supply line 32 to the organic EL element 21 through the drive transistor 22. Consequently, the organic EL element 21 emits light with a luminance corresponding to the current value of the drive current I_{ds}.

### (Threshold Correction Preparation Period)

At time t₁₁, the operation enters a new display frame (a present display frame) for line-sequential scanning. As illustrated in FIG. 4B, the potential DS of the power-supply line 32 is switched from the high potential V_{ccp} to the second power-supply potential (hereinafter referred to as a “low potential”) Vᵢₙᵢ, which is sufficiently lower than V_{ofs}−Vₜₕ relative to the reference potential V_{ofs} of the signal line 33.

Let Vₜₕₑ₁ be a threshold voltage of the organic EL element 21 and let V_{cath} be the potential (cathode potential) of the common power-supply line 34. In this case, when the low potential Vᵢₙᵢ is assumed to satisfy Vᵢₙᵢ<Vₜₕₑ₁+V_{cath}, the source potential Vₛ of the drive transistor 22 is substantially equal to the low potential Vᵢₙᵢ. As a result, the organic EL element 21 is put into a reverse-biased state and turns off the light emission.

Next, at time t₁₂, the potential WS of the scan line 31 shifts from a low-potential side toward a high-potential side, so that the write transistor 23 is put into a conductive state, as illustrated in FIG. 4C. At this point, since the reference potential V_{ofs} is supplied from the signal output circuit 60 to the signal line 33, the gate potential V_{g} of the drive transistor 22 acts as the reference potential V_{ofs}. The source potential Vₛ of the drive transistor 22 is equal to the potential Vᵢₙᵢ that is sufficiently lower than the reference potential V_{ofs}, i.e., is equal to the low potential Vᵢₙᵢ.

At this point, the gate-source voltage V_{gs} of the drive transistor 22 is equal to V_{ofs}−Vᵢₙᵢ. In this case, unless V_{ofs}−Vᵢₙᵢ is sufficiently larger than the threshold voltage Vₜₕ of the drive transistor 22, it is difficult to perform threshold correction processing described below. Thus, setting is performed so as to satisfy a potential relationship expressed by V_{ofs}−Vᵢₙᵢ>Vₜₕ.

Processing for initialization by fixing (setting) the gate potential V_{g} of the drive transistor 22 to the reference potential Vₐₛ and fixing the source potential Vₛ to the low potential Vᵢₙᵢ is processing for preparation (threshold correction preparation) before the threshold correction processing (threshold correction operation) described below is performed. Thus, the reference potential V_{ofs} and the low potential Vᵢₙᵢ serve as initialization potentials for the gate potential V_{g} and the source potential Vₛ of the drive transistor 22.

### (Threshold Correction Period)

Next, at time t₁₃, the potential DS of the power-supply line 32 is switched from the low potential Vᵢₙᵢ to the high potential V_{ccp}, as illustrated in FIG. 4D, and the threshold correction processing is started while the gate potential V_{g} of the drive transistor 22 is maintained at the reference voltage V_{ofs}. That is, the source potential Vₛ of the drive transistor 22 starts to increase toward a potential obtained by subtracting the threshold voltage Vₜₕ of the drive transistor 22 from the gate potential V_{g}.

Herein, the processing for changing the source potential Vₛ toward the potential obtained by subtracting the threshold voltage Vₜₕ of the drive transistor 22 from the initialization potential V_{ofs}, with reference to the initialization potential V_{ofs} of the gate potential V_{g} of the drive transistor 22, is referred to as “threshold correction processing”, for convenience of description. When the threshold correction processing progresses, the gate-source voltage V_{gs} of the drive transistor 22 eventually settles to the threshold voltage Vₜₕ of the drive transistor 22. A voltage corresponding to the threshold voltage Vₜₕ is stored by the storage capacitor 24.

In the period in which the threshold correction processing is performed (i.e., in a threshold correction period), the potential V_{cath} of the common power-supply line 34 is set so that the organic EL element 21 is put into a cutoff state, in order to cause current to flow to the storage capacitor 24 and to prevent current from flowing to the organic EL element 21.

Next, at time t₁₄, the potential WS of the scan line 31 shifts toward the low-potential side, so that the write transistor 23 is put into a non-conductive state, as illustrated in FIG. 5A. At this point, the gate electrode of the drive transistor 22 is electrically disconnected from the signal line 33, so that the gate electrode of the drive transistor 22 enters a floating state. However, since the gate-source voltage V_{gs} is equal to the threshold voltage Vₜₕ of the drive transistor 22, the drive transistor 22 is in a cutoff state. Thus, almost no drain-source current I_{ds} flows to the drive transistor 22.

### (Signal Writing & Mobility Correction Period)

Next, at time t₁₅, as illustrated in FIG. 5B, the potential of the signal line 33 is switched from the reference potential V_{ofs} to the signal voltage V_{sig} of the video signal. Subsequently, at time t₁₆, the potential WS of the scan line 31 shifts toward the high-potential side, so that the write transistor 23 enters a conductive state, as illustrated in FIG. 5C, to sample the signal voltage V_{sig} of the video signal and to write the signal voltage V_{sig} to the pixel 20.

When the write transistor 23 writes the signal voltage V_{sig}, the gate potential V_{g} of the drive transistor 22 becomes equal to the signal voltage V_{sig}. When the drive transistor 22 is driven with the signal voltage V_{sig} of the video signal, the threshold voltage Vₜₕ of the drive transistor 22 is cancelled out by a voltage corresponding to the threshold voltage Vₜₕ stored by the storage capacitor 24. Details of the principle of the threshold cancellation are described below.

At this point, the organic EL element 21 is in the cutoff state (a high impedance state). Thus, the current (the drain-source current I_{ds}) flowing from the power-supply line 32 to the drive transistor 22 in accordance with the signal voltage V_{sig} of the video signal flows to the equivalent capacitor of the organic EL element 21 and the auxiliary capacitor 25. As a result, charging of the equivalent capacitor of the organic EL element 21 and the auxiliary capacitor 25 is started.

As a result of the charging of the equivalent capacitor of the organic EL element 21 and the auxiliary capacitor 25, the source potential Vₛ of the drive transistor 22 increases with a lapse of time. Since variations in the threshold voltages Vₜₕ of the drive transistors 22 of the pixels have already been cancelled out at this point, the drain-source current I_{ds} of the drive transistor 22 depends on the mobility μ of the drive transistor 22. The mobility μ of the drive transistor 22 refers to mobility of a semiconductor thin film included in a channel of the drive transistor 22.

It is now assumed that the ratio of the voltage V_{gs} stored by the storage capacitor 24 to the signal voltage V_{sig} of the video signal (the ratio is referred to as a “write gain G”) is 1 (an ideal value). In this case, the source potential Vₛ of the drive transistor 22 increases to a potential expressed by V_{ofs}−Vₜₕ+ΔV, so that the gate-source voltage V_{gs} of the drive transistor 22 reaches a value expressed by V_{sig}−V_{ofs}+Vₜₕ−ΔV.

That is, an increase ΔV in the source potential Vₛ of the drive transistor 22 acts so that it is subtracted from the voltage (V_{sig}−V_{ofs}+Vₜₕ) stored by the storage capacitor 24, i.e., so that the electrical charge in the storage capacitor 24 is discharged. In other words, negative feedback corresponding to the increase ΔV in the source potential Vₛ is applied to the storage capacitor 24. Thus, the increase ΔV in the source potential Vₛ corresponds to the amount of negative feedback.

When negative feedback having the amount ΔV of feedback corresponding to the drain-source current I_{ds} flowing to the drive transistor 22 is applied to the gate-source voltage V_{gs} in the manner described above, it is possible to cancel the dependence of the drain-source current I_{ds} of the drive transistor 22 upon the mobility μ. This processing for cancelling the dependence on the mobility μ is mobility correction processing for correcting variations in the mobilities μ of the drive transistors 22 of the individual pixels.

More specifically, the higher the signal amplitude Vᵢₙ (=V_{sig}−V_{ofs}) of the video signal written to the gate electrode of the drive transistor 22, the larger the drain-source current I_{ds} is. Thus, the absolute value of the amount ΔV of negative feedback also increases. Accordingly, the mobility correction processing is performed in accordance with the light-emission luminance level.

When the signal amplitude Vᵢₙ of the video signal is constant, the absolute value of the amount ΔV of negative feedback increases as the mobility μ of the drive transistor 22 increases. Thus, variations in the mobilities μ of individual pixels can be reduced or eliminated. That is, the amount ΔV of negative feedback can also be referred to as the “amount of correction of the mobility correction processing”. Details of the principle of the mobility correction are described below.

### (Light Emission Period)

Next, at time t₁₇, the potential WS of the scan line 31 shifts toward the low-potential side, so that the write transistor 23 is put into a non-conductive state, as illustrated in FIG. 5D. Consequently, the gate electrode of the drive transistor 22 is electrically disconnected from the signal line 33, so that the gate electrode of the drive transistor 22 enters a floating state.

In this case, when the gate electrode of the drive transistor 22 is in the floating state, the gate potential V_{g} also varies in conjunction with variations in the source potential Vₛ of the drive transistor 22, since the storage capacitor 24 is connected between the gate and the source of the drive transistor 22.

Such an operation in which the gate potential V_{g} of the drive transistor 22 varies in conjunction with variations in the source potential Vₛ, that is, an operation in which the gate potential V_{g} and the source potential Vₛ increases while the gate-source voltage V_{gs} stored in the storage capacitor 24 is maintained, is herein referred to as a “bootstrap operation”.

At the same time the gate electrode of the drive transistor 22 enters the floating state, the drain-source current I_{ds} of the drive transistor 22 starts to flow to the organic EL element 21, so that the anode potential of the organic EL element 21 increases in response to the drain-source current I_{ds}.

When the anode potential of the organic EL element 21 exceeds Vₜₕₑ₁+V_{cath}, the drive current starts to flow to the organic EL element 21 to thereby cause the organic EL element 21 to start light emission. The increase in the anode potential of the organic EL element 21 is due to an increase in the source potential Vₛ of the drive transistor 22. When the source potential Vₛ of the drive transistor 22 increases, the bootstrap operation of the storage capacitor 24 causes the gate potential V_{g} of the drive transistor 22 to increase in conjunction with the source potential Vₛ.

When the gain of the bootstrap is assumed to be 1 (an ideal value), the amount of increase in the gate potential V_{g} is equal to the amount of increase in the source potential Vₛ. Therefore, in the light-emission period, the gate-source voltage V_{gs} of the drive transistor 22 is maintained constant at V_{sig}−V_{ofs}+Vₜₕ−ΔV. At time t₁₈, the potential of the signal line 33 is switched from the signal voltage V_{sig} of the video signal to the reference voltage V_{ofs}.

In the above-described series of circuit operations, the processing operations of the threshold correction preparation, the threshold correction, the writing (signal writing) of the signal voltage V_{sig}, and the mobility correction are executed in one horizontal scan period (1H). The processing operations of the signal writing and the mobility correction are executed in parallel in the period of time t₁₆ to time t₁₇.

### [Division Threshold Correction]

Although the above description has been given of an example using a drive method for executing the threshold correction processing only once, the drive method is merely one example and is not limited thereto. For example, a drive method for performing so-called “division threshold correction” may also be employed. In the division threshold correction, in addition to the 1H period in which the threshold correction processing is performed in conjunction with the mobility correction and the signal write processing, the threshold correction processing is performed multiple times, i.e., in multiple horizontal scan periods in a divided manner, prior to the 1H period.

With the drive method for the division threshold correction, even when a time allocated to one horizontal scan period is reduced as a result of an increased number of pixels for a higher definition, a sufficient amount of time can be ensured in the multiple scan periods for the threshold correction periods. Thus, since a sufficient amount of time can be ensured as a threshold correction period even when the time allocated to one horizontal scan period is reduced, it is possible to reliably execute the threshold correction processing.

### [Principle of Threshold Cancellation]

The principle of the threshold cancellation (i.e., threshold correction) of the drive transistor 22 will now be described. Since the drive transistor 22 is designed so as to operate in the saturation region, it operates as a constant current source. As a result, a certain amount of drain-source current (drive current) I_{ds} flows from the drive transistor 22 to the organic EL element 21, and is given by:

I_{ds}=(½)·μ(W/L)Cₒₓ(V_{gs}−Vₜₕ)² (1)

where W indicates a channel width of the drive transistor 22, L indicates a channel length, and Cₒₓ indicates a gate capacitance per unit area.

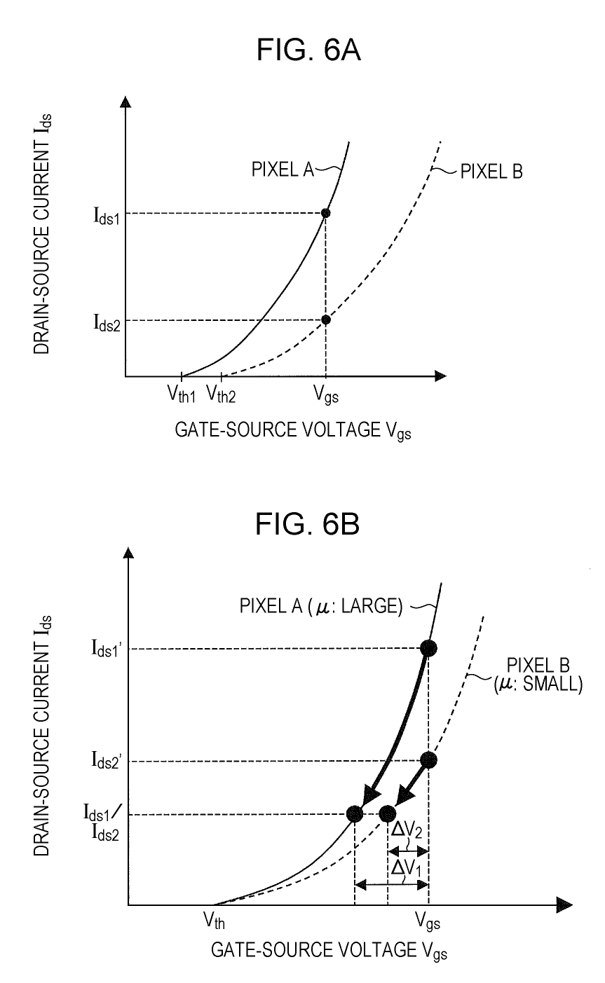

FIG. 6A is a graph illustrating a characteristic of the drain-source current I_{ds} of the drive transistor 22 versus the gate-source voltage V_{gs}. As illustrated in the graph in FIG. 6A, if no cancellation processing (correction processing) is performed on variations in the threshold voltage Vₜₕ of the drive transistor 22 in each individual pixel, the drain-source current I_{ds} corresponding to the gate-source voltage V_{gs} becomes I_{ds1} when the threshold voltage Vₜₕ is Vₜₕ₁.

In contrast, when the threshold voltage Vₜₕ is Vₜₕ₂ (Vₜₕ₂>Vₜₕ₁), the drain-source current I_{ds} corresponding to the same gate-source voltage V_{gs} becomes I_{ds2} (I_{ds2}<I_{ds1}). That is, when the threshold voltage Vₜₕ of the drive transistor 22 varies, the drain-source current I_{ds} varies even when the gate-source voltage V_{gs} is constant.

On the other hand, in the pixel (pixel circuit) 20 having the above-described configuration, the gate-source voltage V_{gs} of the drive transistor 22 during light emission is expressed by V_{sig}−V_{ofs}+Vₜₕ−ΔV, as described above. Thus, substituting this expression into equation (1) noted above yields a drain-source current I_{ds} given by:

I_{ds}=(½)·μ(W/L)Cₒₓ(V_{sig}−V_{ofs}−ΔV)² (2)

That is, the term of the threshold voltage Vₜₕ of the drive transistor 22 is cancelled, so that the drain-source current I_{ds} supplied from the drive transistor 22 to the organic EL element 21 does not depend on the threshold voltage Vₜₕ of the drive transistor 22. As a result, even when the threshold voltage Vₜₕ of the drive transistor 22 is varied for each pixel by variations in the manufacturing process of the drive transistor 22, aging, or the like, the drain-source current I_{ds} does not vary. Accordingly, the light-emission luminance of the organic EL element 21 can be maintained constant.

### [Principle of Mobility Correction]

The principle of the mobility correction of the drive transistor 22 will be described next. FIG. 6B is a graph illustrating characteristic curves for comparison between a pixel A in which the mobility μ of the drive transistor 22 is relatively large and a pixel B in which the mobility μ of the drive transistor 22 is relatively small. When the drive transistor 22 is implemented by a polysilicon TFT or the like, variations in the mobilities μ of the pixels occur, such as those in pixels A and B.

A description will now be given of an example in which the signal amplitudes Vᵢₙ (=V_{sig}−V_{ofs}) at the same level are written to the gate electrodes of the drive transistors 22 of pixels A and B when mobilities μ in pixels A and B have variations. In this case, if no correction is performed on the mobilities μ, a large difference occurs between a drain-source current I_{ds1}′ flowing through pixel A having a large mobility μ and a drain-source current I_{ds2}′ flowing through pixel B having a small mobility μ. When a large difference occurs between the drain-source currents I_{ds} in the pixels as a result of variations in the mobilities μ of the pixels, uniformity on the screen is impaired.

As is apparent from the transistor characteristic given by equation (1) noted above, the drain-source current I_{ds} increases as the mobility μ increases. Thus, the amount ΔV of negative feedback increases as the mobility μ increases. As illustrated in FIG. 6B, the amount ΔV₁ of negative feedback in pixel A having a large mobility μ is larger than the amount ΔV₂ of negative feedback in pixel B having a small mobility μ.

Accordingly, when the mobility correction processing is performed so that negative feedback having the amount ΔV of feedback corresponding to the drain-source current I_{ds} of the drive transistor 22 is applied to the gate-source voltage V_{gs}, a larger amount of negative feedback is applied as the mobility μ increases. As a result, it is possible to suppress variations in the mobilities μ of the pixels.

More specifically, when correction corresponding to the amount ΔV₁ of negative feedback is performed on pixel A having a large mobility μ, the drain-source current I_{ds} decreases significantly from I_{ds1}′ to I_{ds1}. On the other hand, since the amount ΔV₂ of feedback in pixel B having a small mobility μ is small, the drain-source current I_{ds} decreases from I_{ds2}′ to I_{ds2} and the amount of this decrease is not so large. As a result, the drain-source current I_{ds1} in pixel A and the drain-source current I_{ds2} in pixel B become substantially equal to each other, so that variations in the mobilities μ of the pixels are corrected.

In short, when pixels A and B having different mobilities μ exist, the amount ΔV₁ of feedback in pixel A having a large mobility μ is larger than the amount ΔV₂ of feedback in pixel B having a small mobility μ. That is, the larger the mobility μ of the pixel, the larger the amount of feedback ΔV is and also the larger the amount of decrease in the drain-source current I_{ds} is.

Thus, as a result of applying the negative feedback having the amount ΔV of feedback corresponding to the drain-source current I_{ds} of the drive transistor 22 to the gate-source voltage V_{gs}, the current values of the drain-source currents I_{ds} of the pixels having different mobilities μ become equal to each other. As a result, it is possible to correct variations in the mobilities μ of the pixels. That is, the mobility correction processing is processing in which the negative feedback having the amount ΔV of feedback (the amount of correction) corresponding to the current (drain-source current I_{ds}) flowing to the drive transistor 22 is applied to the gate-source voltage V_{gs} of the drive transistor 22, i.e., to the storage capacitor 24. The threshold correction and the mobility correction described above are operations that may or may not be performed in the present disclosure and the various corrections, light emissions, and so on described above are not limited to those operations and timings.

### 1-3. Bottom Gate Structure and Top Gate Structure

In the organic EL display device 10 having the above-described configuration, the transistors in the pixel 20, specifically, the TFTs constituting the drive transistor 22 and the write transistor 23, are broadly classified into a bottom gate structure and a top gate structure in terms of the structure. In the bottom gate structure, the gate electrode is located closer to the substrate side relative to the semiconductor layer. In the top gate structure, the gate electrode is located at the opposite side of the substrate relative to the semiconductor layer.

When a TFT having the bottom gate structure is used as a transistor in the pixel 20, a semiconductor layer and a thin insulating film lie between the metal layer of the gate electrode and the metal layer of the source/drain electrode. Accordingly, arrangement of the metal layer of the gate electrode and the metal layer of the source/drain electrode so as to oppose each other allows a capacitor using a thin insulating film as a dielectric to be formed between those metal layers. The capacitor formed between those metal layers with the insulting film being interposed therebetween can be used as a capacitance element to be fabricated in the pixel 20, for example, as the auxiliary capacitor 25 serving as an auxiliary of the equivalent capacitor of the organic EL element 21.

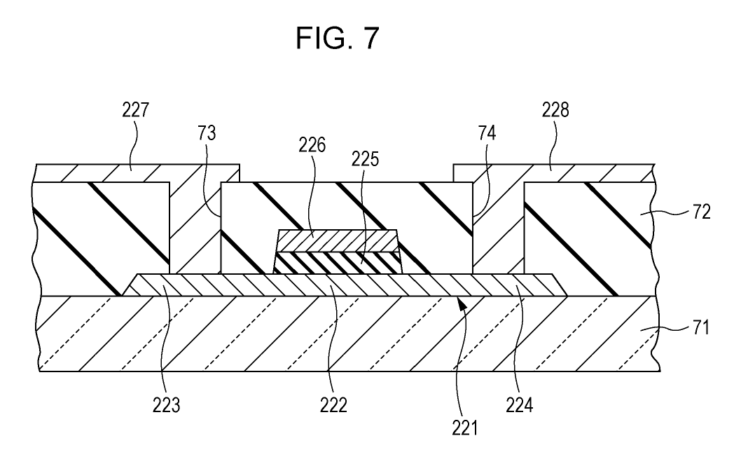

On the other hand, when a TFT having the top gate structure is used as a transistor in the pixel 20, an insulating planarization film is formed on a circuit section including the transistors and so on in order to planarize an upper portion of the circuit section and the metal layer of a source/drain electrode is formed on the insulating planarization film. A case in which the transistor in the pixel 20 is the drive transistor 22 will now be described in more detail with reference to FIG. 7.

As illustrated in FIG. 7, a semiconductor layer 221 of the drive transistor 22 is formed on a substrate, for example, a glass substrate 71. A center region of the semiconductor layer 221 serves as a channel region 222 and two opposite ends of the channel region 222 serve as source/drain regions 223 and 224. A gate insulating film 225 is deposited on the channel region 222 of the semiconductor layer 221 and a gate electrode 226 is formed on the gate insulating film 225.

In order to planarize an upper portion of the TFT circuit section including the thus-formed drive transistor 22, an insulating planarization film 72 is formed on the TFT circuit section including the drive transistor 22. Contact holes 73 and 74 are formed in the insulating planarization film 72 so as to communicate with the corresponding source/drain regions 223 and 224 at the two opposite ends of the semiconductor layer 221. Source/drain electrodes 227 and 228 are formed on the insulating planarization film 72 and the contact holes 73 and 74 are filled with a wiring material (electrode material), so that the source/drain electrodes 227 and 228 are electrically connected with the source/drain regions 223 and 224, respectively.

As described above, when the transistor in the pixel 20 is implemented by a TFT having the top gate structure, the insulating planarization film 72 is mainly provided for the planarization. Thus, the thickness of the insulating planarization film 72 is considerably larger than the thickness of the gate insulating film 225. The large thickness of the insulating planarization film 72 makes it difficult to form a capacitor between the metal layer of the gate electrode 226 and the metal layer of the source/drain electrodes 227 and 228.

For such a reason, if the capacitance element to be fabricated in the pixel 20 can be formed in a region other than a region between those metal layers, the degree of freedom of the cross-sectional structure of the pixel 20 can be improved. The same is true not only for the case in which a TFT having the top gate structure is used as the transistor in the pixel 20 but also for a case in which a TFT having the bottom gate structure is used.

### 2. EMBODIMENTS

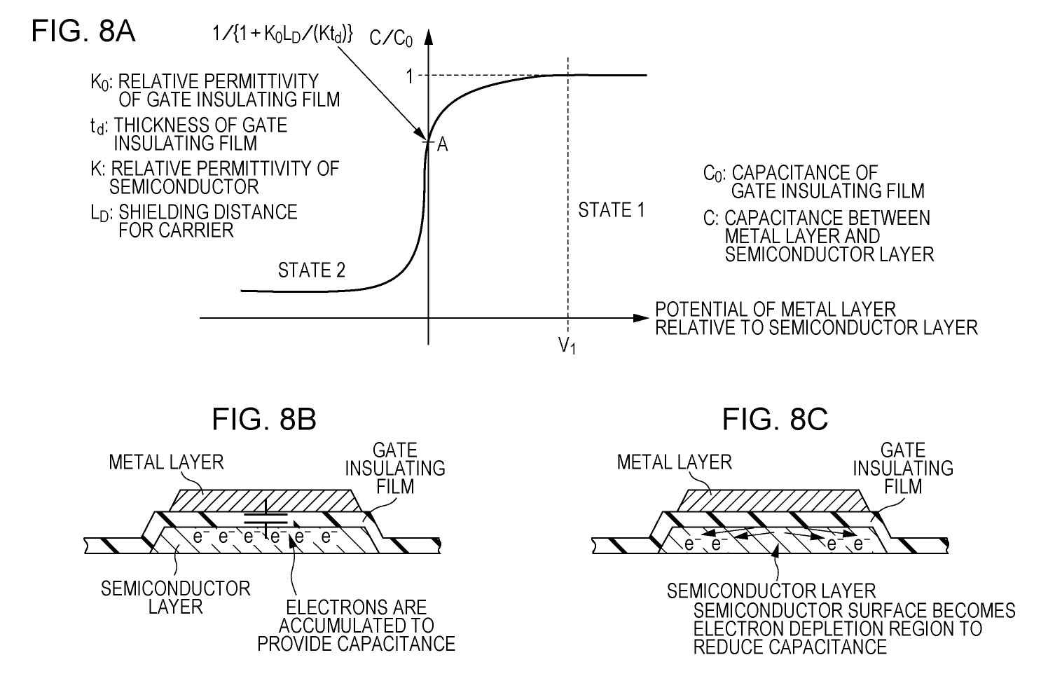

In order to improve the degree of freedom of the cross-sectional structure of the pixel 20, the embodiment of the present disclosure employs a configuration in which a capacitance element to be fabricated in the pixel 20 is formed between the same metal layer as the layer of the gate electrode of the transistor and the semiconductor layer in which the source/drain region of the transistor is formed. Formation of the capacitance element between the metal layer and the semiconductor layer involves application of a voltage to the metal layer. The reason why a voltage is applied to the metal layer to form the capacitance element between the metal layer and the semiconductor layer will now be described with reference to FIGS. 8A to 8C.

FIG. 8A illustrates a C-V (capacitance-voltage) characteristic of the semiconductor layer and the metal layer during a high-frequency operation, such as an operation for driving the pixel 20. In the C-V characteristic in FIG. 8A, the horizontal axis indicates the potential of the metal layer relative to the semiconductor layer. The vertical axis indicates a ratio C/C₀, where C₀ indicates a capacitance of the gate insulating film and C indicates a capacitance between the metal layer and the semiconductor layer and.

In the C-V characteristic in FIG. 8A, C/C₀ at point A at which a characteristic curve intersects the vertical axis is given by:

A(C/C₀)=1/{1+K₀L_{D}/(Kt_{d})}

where K₀ indicates a relative permittivity of the gate insulating film, td indicates the thickness of the gate insulating film, K indicates a relative permittivity of the semiconductor, and L_{D} indicates a shielding distance for a carrier.

A case in which the transistor in the pixel 20 is an N-channel MOS transistor will now be discussed by way of example.

For an N-channel MOS transistor, when a sufficiently high voltage relative to the voltage at the semiconductor layer is applied to the metal layer, electrons are accumulated at the surface of the semiconductor layer, that is, a channel is formed at the surface of the semiconductor layer, as illustrated in FIG. 8B (which corresponds to state 1 illustrated in FIG. 8A). Thus, the gate insulating film interposed between the semiconductor layer and the metal layer is used as a dielectric to form a capacitor. That is, a voltage with which a sufficient amount of channel is formed at the surface of the semiconductor layer is applied to the metal layer.

In the C-V characteristic in FIG. 8A, V₁ indicates a voltage value with which the capacitance C₀ of the gate insulating film becomes visible, in other words, indicates a voltage value with which the capacitance C₀ of the gate insulating film that is a dielectric becomes equal to the capacitance C between the metal layer and the semiconductor layer (i.e., C/C₀=1). On the other hand, when a low voltage relative to the voltage at the semiconductor layer is applied to the metal layer, the area of an electron depletion region increases at the surface of the semiconductor layer, as illustrated in FIG. 8B (which corresponds to state 2 illustrated in FIG. 8A). This reduces the capacitance value of the capacitor that is formed between the semiconductor layer and the metal layer and that uses the gate insulating film as a dielectric.

As is apparent from the above description, in the pixel structure in which the metal layer and the semiconductor layer are arranged so as to oppose each other with the gate insulating film interposed therebetween, application of a voltage to the metal layer causes formation of a channel at the surface of the semiconductor layer. This makes it possible to form a capacitor using the gate insulating film as a dielectric. The capacitor may further be used as a capacitance element to be fabricated in the pixel 20, for example, as the auxiliary capacitor 25 in the pixel circuit illustrated in FIG. 2. With such an arrangement, since the capacitance element to be fabricated in the pixel 20 can be formed in a region other than the region between the metal layers, the degree of freedom of the cross-sectional structure of the pixel 20 can be improved.

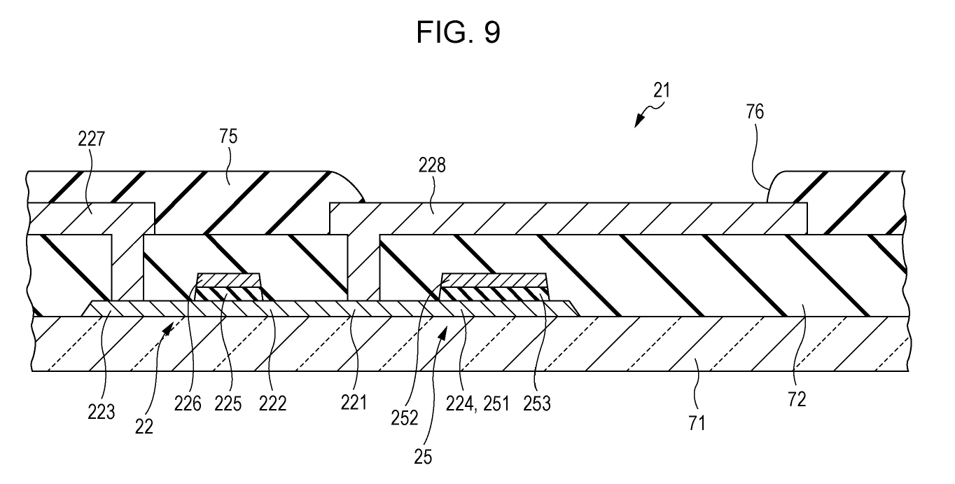

FIG. 9 is a cross-sectional view illustrating a cross-sectional structure of the pixel according to the embodiment of the present disclosure. FIG. 9 illustrates the drive transistor 22 and the auxiliary capacitor 25 in the pixel circuit illustrated in FIG. 2, that is, illustrates an example in which the capacitor that is formed between the metal layer and the semiconductor layer and that uses the gate insulating film as a dielectric is used as the auxiliary capacitor 25. In FIG. 9 the same portions as those in FIG. 7 are denoted by the same reference numerals.

As described above with reference to FIG. 7, the TFT circuit section including the drive transistor 22 is formed on a glass substrate 71. The drive transistor 22 includes a semiconductor layer 221 formed on the glass substrate 71, a gate electrode 226 disposed so as to oppose a channel region 222 of the semiconductor layer 221, and a gate insulating film 225 disposed between the semiconductor layer 221 and a gate electrode 226. In the semiconductor layer 221, the two opposite ends of the channel region 222 serve as source/drain regions 223 and 224, respectively.

An insulating planarization film 72 is formed on the TFT circuit section including the drive transistor 22 in order to planarize the upper portion thereof. A wiring layer including source/drain electrodes 227 and 228 is formed on the insulating planarization film 72. In this example, the source/drain electrode 228 at one side of the drive transistor 22 is adapted so as to also serve as an anode electrode of the organic EL element 21. A window insulating film 75 is formed on the wiring layer including the source/drain electrodes 227 and 228. An organic layer (not illustrated) of the organic EL element 21 is formed in an opening portion (depression portion) 76 in the window insulating film 75 and a cathode electrode (not illustrated, common to all pixels) of the organic EL element 21 is formed on the window insulating film 75.

In the pixel structure having the above-described configuration, the semiconductor layer 221 is provided so as to extend in the lower portion in the organic EL element 21. One end of the semiconductor layer 221, i.e., a source-drain electrode 224, also serves as a first electrode 251 of the auxiliary capacitor 25. A second electrode 252 of the auxiliary capacitor 25 is formed in the same layer as the layer of the gate electrode 226 of the drive transistor 22 so as to oppose the first electrode 251. A gate insulating film 253 is provided between the first electrode 251 and the second electrode 252.

As described above, a voltage with which a sufficient amount of channel is formed at the surface of the semiconductor layer 221, i.e., at the surface of the first electrode 251, is applied to the second electrode 252 that is a metal layer. As a result, electrons are accumulated at the surface of the semiconductor layer 221, so that a capacitor using the gate insulating film 253 as a dielectric is formed to serve as a capacitance element to be fabricated in the pixel 20, i.e., to serve as the auxiliary capacitor 25 in this example.

A case in which the first electrode 251 of the auxiliary capacitor 25 is implemented by the semiconductor layer 221 and the second electrode 252 of the auxiliary capacitor 25 is implemented by the metal layer, as described above, will be described below with reference to specific embodiments in which a voltage is applied to the second electrode 252.

### 2-1. First Embodiment

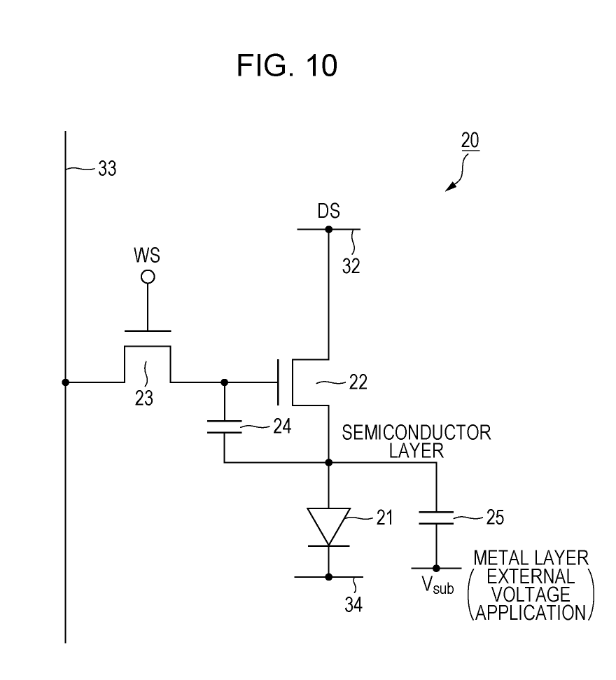

FIG. 10 is a circuit diagram of a pixel circuit according to a first embodiment. In FIG. 10, the same portions as those in FIG. 2 are denoted by the same reference numerals.

The pixel circuit according to the first embodiment employs a configuration in which the second electrode of the auxiliary capacitor 25 is open rather than being connected to a common power-supply line 34 at a ground level, unlike the case of the pixel circuit illustrated in FIG. 2, and a constant voltage V_{sub} is applied from an external power source (not illustrated) to the second electrode.

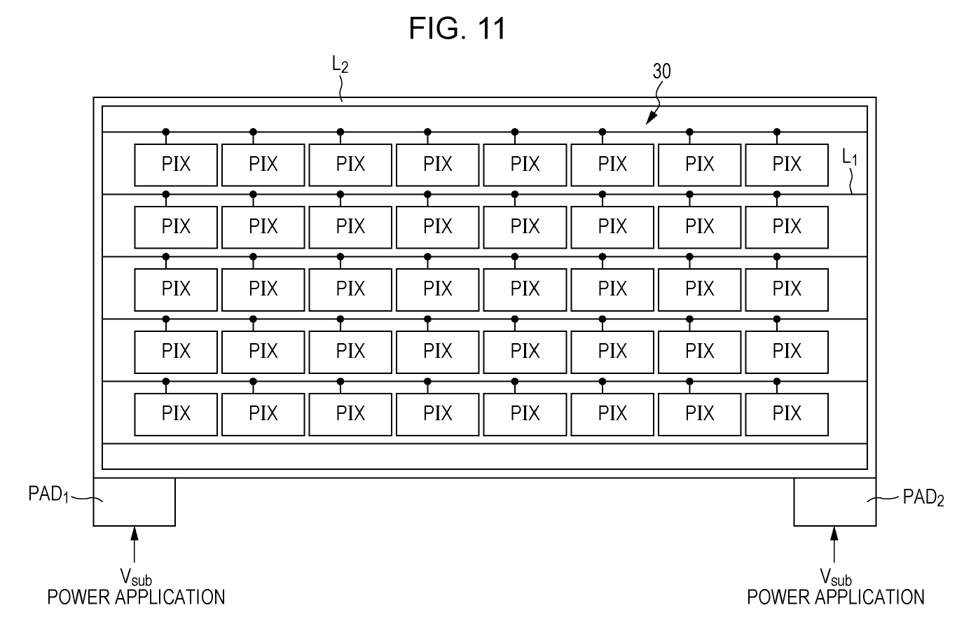

FIG. 11 illustrates a layout example of a panel for applying a constant voltage V_{sub} from the external power supply to the second electrodes of the auxiliary capacitors 25. As illustrated in FIG. 11, voltage-supply lines L₁ are connected to the second electrodes of the auxiliary capacitors 25 in the pixel circuits in corresponding rows. The voltage-supply lines L₁ are bundled together at a peripheral portion of the pixel array section 30 to form a common power-supply line L₂, for example, in a looped shape around the pixel array section 30. Pads PAD₁ and PAD₂ are formed at two opposite ends (left and right ends) of the panel and are connected to the looped common power-supply line L₂. The constant voltage V_{sub} is supplied from an external power source (not illustrated) of the panel to the second electrodes of the auxiliary capacitors 25 through the pads PAD₁ and PAD₂, the common power-supply line L₂, and the voltage-supply lines L₁.

With such an arrangement in which a voltage is applied to the looped common power-supply line L₂ through the pads PAD₁ and PAD₂ at the two opposite ends of the panel, the constant voltage V_{sub} can be stably supplied to the second electrodes of the auxiliary capacitors 25 in the pixels. This arrangement can reduce variations in capacitance values C_{sub} of the auxiliary capacitors 25 in the pixels, so that the pixel circuits can be driven with the stable capacitance values C_{sub} of the auxiliary capacitors 25.

In this case, it is preferable that the constant voltage V_{sub} externally supplied has the above-described voltage value V₁ (i.e., the voltage value with which the capacitance C₀ of the gate insulating film becomes visible) or larger relative to the source potential of the drive transistor 22 during a high-gradation video signal. If the potential of the second electrode of the auxiliary capacitor 25, i.e., the potential of the metal layer decreases relative to the source potential of the drive transistor 22, i.e., the potential of the semiconductor layer, the capacitance value C_{sub} of the auxiliary capacitor 25 decreases and thus the light-emission luminance of the pixel 20 decreases.

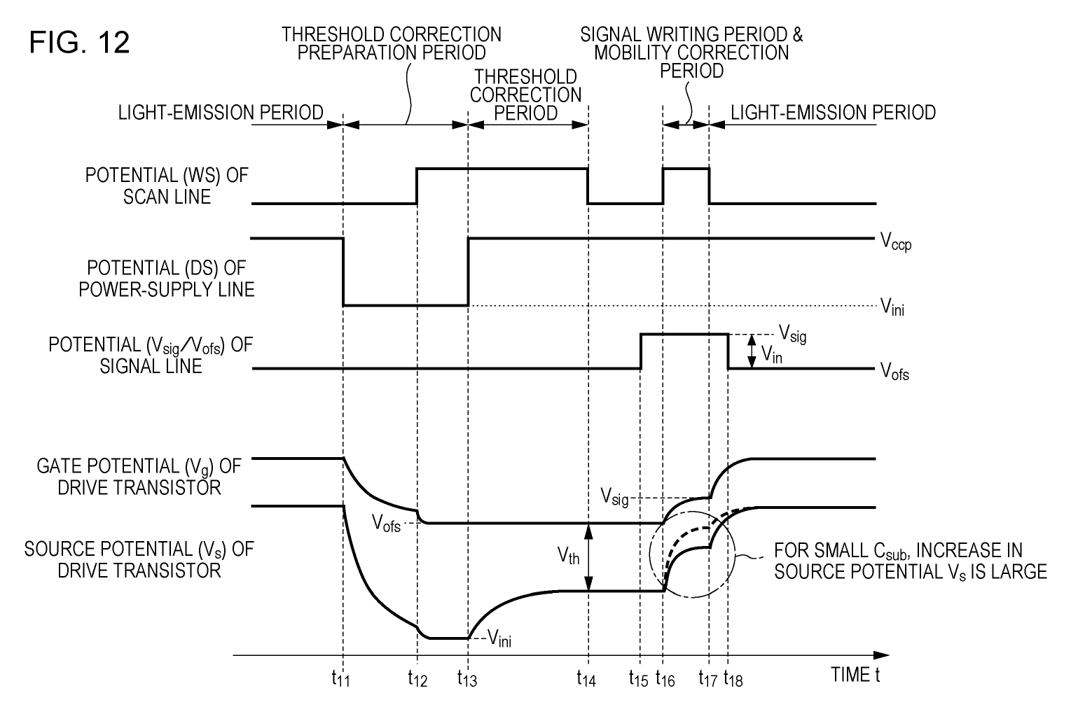

A mechanism in which the luminance decreases when the potential of the metal layer decreases relative to the potential of the semiconductor layer will now be described with reference to a timing waveform diagram illustrated in FIG. 12.

When the capacitance value C_{sub} of the auxiliary capacitor 25 is smaller than a specified value during signal writing and mobility correction, an increase in the source voltage Vₛ when a signal voltage V_{sig} of a video signal is written to the gate of the drive transistor 22 becomes large, as illustrated by a dotted line in FIG. 12. Consequently, the gate-source voltage V_{gs} of the drive transistor 22 immediately before light emission decreases, so that the luminance of the organic EL element 21 decreases.

Letting C_{oled} be the capacitance value of the equivalent capacitance of the organic EL element 21 and letting Cₛ be the capacitance value of the storage capacitor 24, the amount ΔVₛ of increase in the source voltage Vₛ of the drive transistor 22 during signal writing is given by:

ΔVₛ=(V_{sig}−V_{ofs})/(Cₛ+C_{sub}+C_{oled})

If the capacitance value C_{sub} of the auxiliary capacitor 25 varies greatly from a large capacitance value to a small capacitance value during light emission, this results in the same effect as the effect of a case in which the characteristic of the organic EL element 21 shifts to a depletion-type characteristic (though, there is no problem with the pixel circuit according to the first embodiment since it is adapted to apply the constant voltage V_{sub} to the second electrode of the auxiliary capacitor 25). Consequently, an operating point of each organic EL element 21 varies. As a result of variations in the operating points of the organic EL elements 21 in the pixels, luminance non-uniformity occurs.

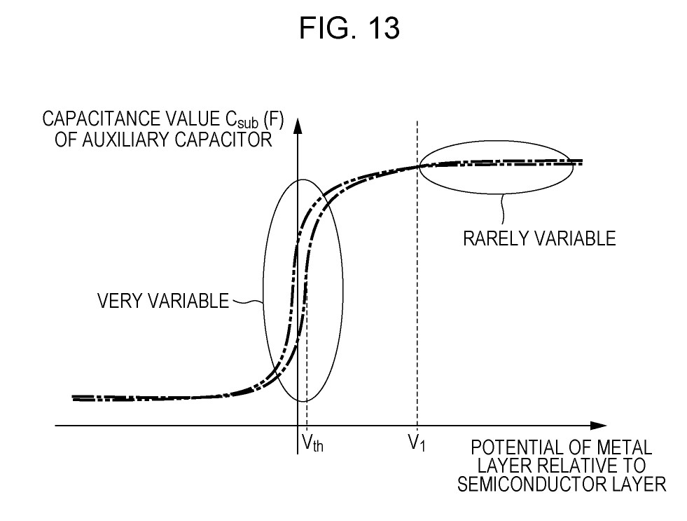

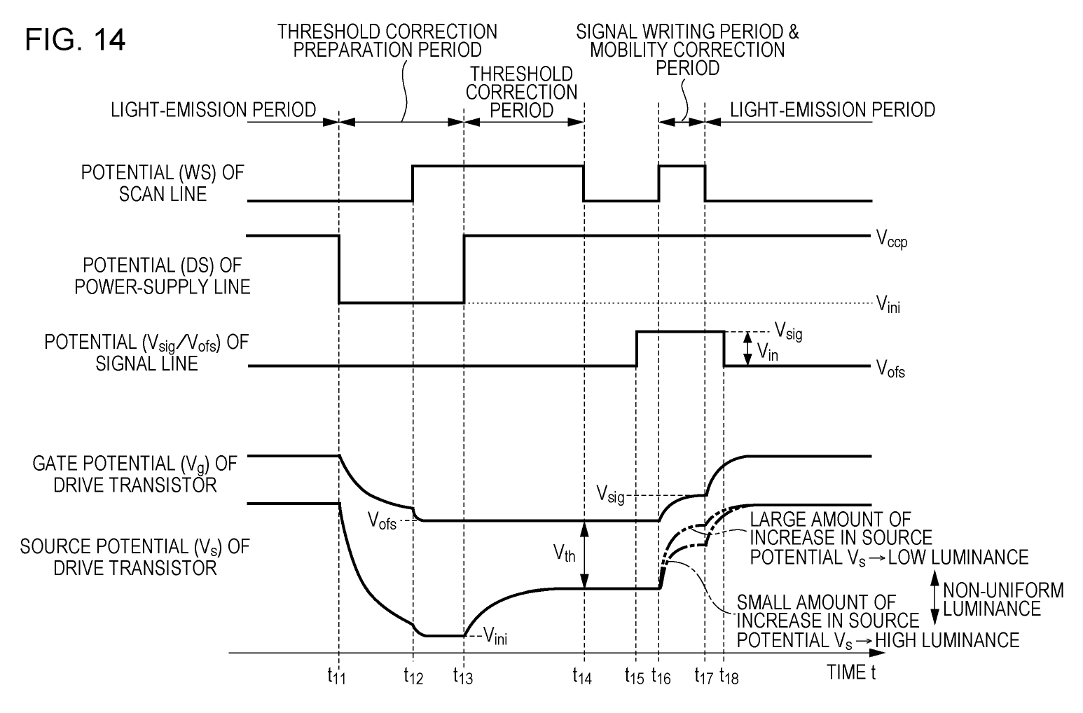

A mechanism in which variations in the operating points of the organic EL elements 21 in the pixels cause luminance non-uniformity will now be described with reference to FIGS. 13 and 14.

As illustrated in FIG. 13, the capacitance characteristic of the semiconductor capacitance is variable at, in the vicinity of a threshold voltage, a point at which the capacitance value Vₜₕ is greatly varied by a voltage. Thus, when the voltage V_{sub} of the second electrode of the auxiliary capacitor 25 is close to the threshold voltage Vₜₕ relative to the potential of the semiconductor layer, that is, relative to the source potential Vₛ of the drive transistor 22, the pixels whose capacitance values C_{sub} of the auxiliary capacitors 25 are large and the pixels whose capacitance values C_{sub} are small coexist in the same panel. In FIG. 13, a characteristic of a pixel whose capacitance value C_{sub} of the auxiliary capacitor 25 is large is indicated by a dashed-dotted line and a characteristic of a pixel whose capacitance value C_{sub} of the auxiliary capacitor 25 is small is indicated by a long dashed double-short dashed line.

With respect to the pixel whose capacitance value C_{sub} of the auxiliary capacitor 25 is large, the luminance increases since the amount of increase in the source voltage Vₛ of the drive transistor 22 is small, as indicated by a dashed-dotted line in FIG. 14. In contrast, with respect to the pixel whose capacitance value C_{sub} of the auxiliary capacitor 25 is small, the luminance decreases since the amount of increase in the source voltage Vₛ of the drive transistor 22 is large, as indicated by a long dashed double-short dashed line in FIG. 14. Thus, since the pixels having high luminances and pixels having low luminances coexist in the same panel, the variations in the luminances are perceived as luminance non-uniformity.

### 2-2. Second Embodiment

A pixel circuit according to a second embodiment will be described next. The pixel circuit according to the second embodiment employs the same circuit configuration as the pixel circuit according to the first embodiment illustrated in FIG. 10. That is, the second electrode of the auxiliary capacitor 25 is open. Although the pixel circuit according to the first embodiment described above is adapted so that the constant voltage V_{sub} is supplied to the second electrode of the auxiliary capacitor 25, the pixel circuit according to the second embodiment employs a configuration in which a pulsed voltage V_{sub} is applied to the second electrode of the auxiliary capacitor 25.

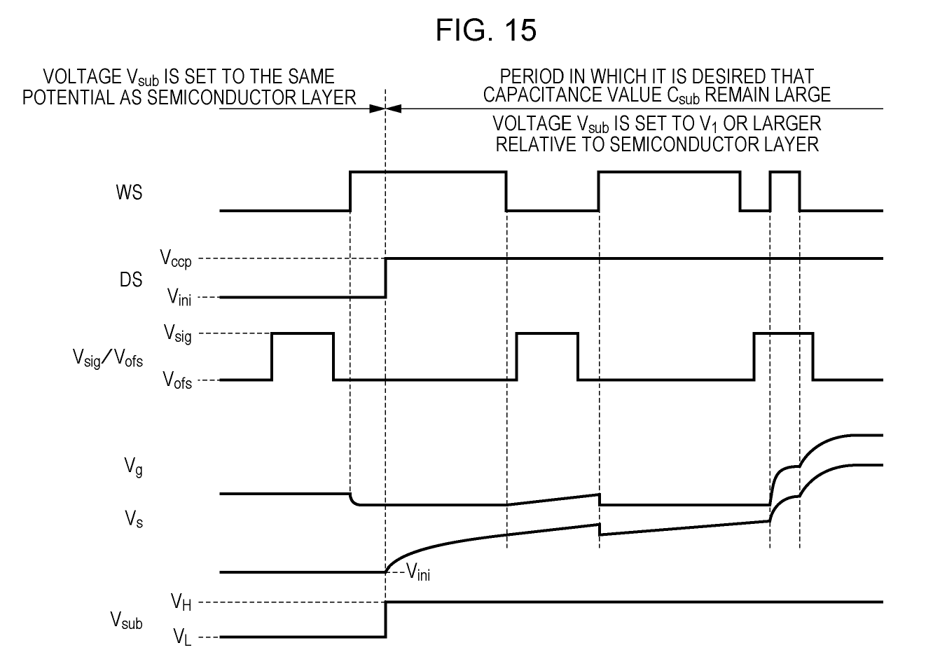

More specifically, in a period in which it is desired that the capacitance value C_{sub} of the auxiliary capacitor 25 remain large, the pulsed voltage V_{sub} is increased to a high voltage V_{H}, as illustrated in the timing waveform in FIG. 15. As is apparent from the above description, the high voltage V_{H} has the voltage value V₁ or larger relative to the source potential of the drive transistor 22 during writing of high-gradation video signals. The period in which it is desired that the capacitance value C_{sub} of the auxiliary capacitor 25 remain large is a period in which the potential DS of the power-supply line 32 is the first power-supply potential V_{ccp}. In a period other than the period in which it is desired that the capacitance value C_{sub} of the auxiliary capacitor 25 remain large, the pulsed voltage V_{sub} is reduced to a low voltage V_{L}.

When a voltage is continuously applied to the metal layer, the characteristic of the capacitor formed between the semiconductor layer and the metal layer shifts to an enhancement-type characteristic and thus the reliability may be reduced. In addition, since the speed at which the characteristic shifts to the enhancement-type characteristic also differs depending on the pixels, the difference in the speed causes variations in the capacitance values of the pixels.

For such a reason, the voltage V_{sub} is pulsed so that the voltage is not continuously applied to the metal layer, in other words, so that the application time of the voltage across the auxiliary capacitor 25 is minimized, thereby making it possible to ensure the reliability of the auxiliary capacitor 25.

In particular, in the period in which the organic EL element 21 does not emit light, the source potential Vₛ of the drive transistor 22 becomes the second power supply potential Vᵢₙᵢ of the potential DS of the power-supply line 32, so that the low voltage V_{L} of the pulsed voltage V_{sub} is used as the second power supply potential Vᵢₙᵢ. As described above, in the period other the period in which it is desired that the capacitance value C_{sub} of the auxiliary capacitor 25 remain large, the potential of the second electrode of the auxiliary capacitor 25 is reduced to the second power supply potential Vᵢₙᵢ to thereby cause the voltage across the auxiliary capacitor 25 to reach 0 V. Since this arrangement can further ensure the reliability of the auxiliary capacitor 25, it is possible to prevent the luminance non-uniformity and luminance reduction which are caused by a decline in the reliability of the capacitor.

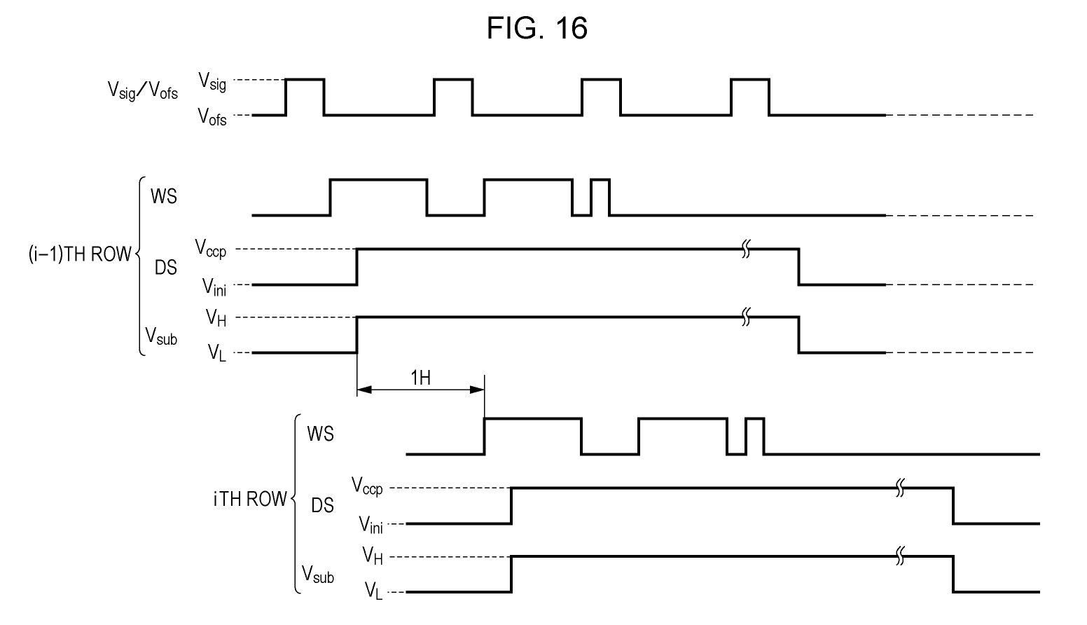

FIG. 16 is a timing waveform diagram illustrating exemplary drive timings according to the second embodiment. FIG. 16 illustrate waveforms of the potentials (scan signals) WS of the scan lines 31, the potentials DS of the power-supply lines 32, and the pulsed voltages V_{sub} with respect to two pixel rows (lines), namely, the (i−1)th pixel row and the ith pixel row.

It is desired that, as illustrated in FIG. 16, the pulsed voltage V_{sub} be offset by 1H (one horizontal period) for each line (each row) so as to synchronize with the corresponding potential DS of the power-supply line 32. As described above, the high voltage V_{H} of the pulsed voltage V_{sub} is set to a voltage having the voltage value V₁ or larger relative to the source potential of the drive transistor 22 during writing of high-gradation video signals and the low voltage V_{L} is used as the second power supply potential Vᵢₙᵢ of the potential DS of the power-supply line 32.

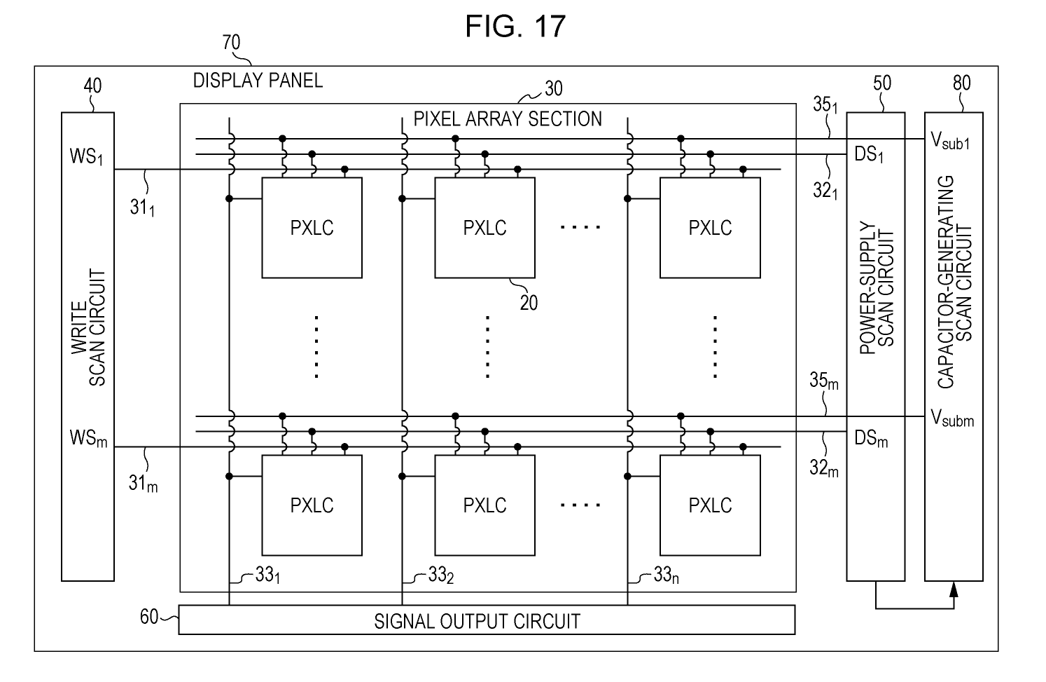

FIG. 17 illustrates an example of a panel configuration for supplying the pulsed voltage V_{sub} to the second electrode of the auxiliary capacitor 25 and for realizing the exemplary drive timings according to the second embodiment.

As illustrated in FIG. 17, in addition to the write scan circuit 40 and the power-supply scan circuit 50, a capacitor-generating scan circuit 80 for generating the auxiliary capacitors 25 is provided, for example, on a display panel 70. The capacitor-generating scan circuit 80 synchronizes with the operation of the power-supply scan circuit 50, specifically, with the potentials DS of the power-supply lines 32 to sequentially output pulsed voltages V_{sub1} to V_{subm} while sequentially scanning the pixel rows, thereby supplying the voltages V_{sub1} to V_{subm} to the second electrodes of the auxiliary capacitors 25 in the pixels 20 through scan lines 35₁ to 35ₘ.

### Modification of Second Embodiment

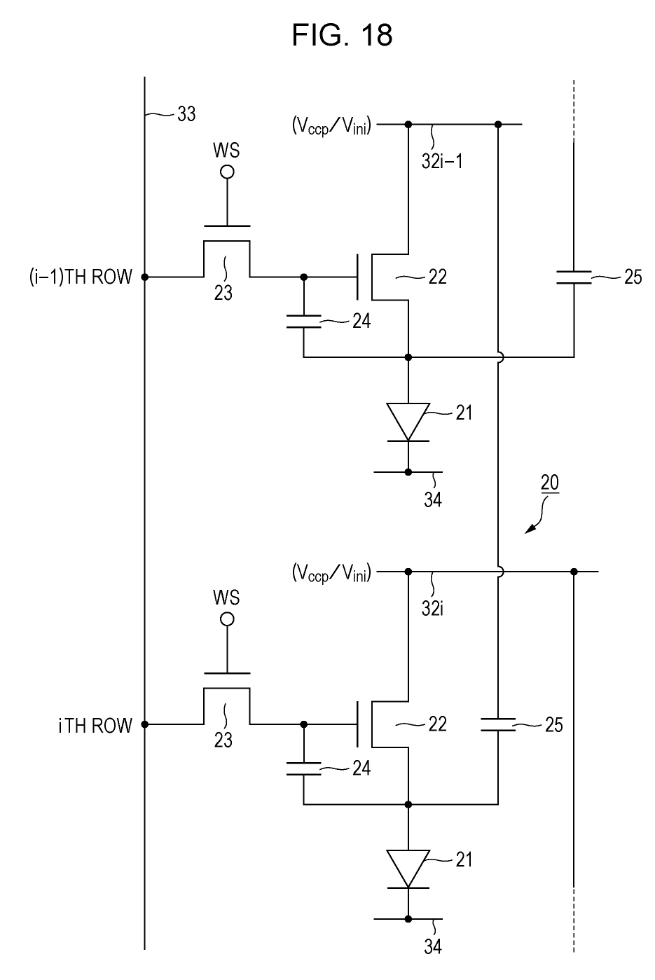

Although the second embodiment employs the configuration in which the dedicated capacitor-generating scan circuit 80 for generating the auxiliary capacitors 25 is provided in order to realize the exemplary drive timings for supplying the pulsed voltages V_{sub} to the second electrodes of the auxiliary capacitors 25, the following configuration may also be employed as a modification. That is, from the viewpoint of using the pulsed voltages V_{sub}, it is also possible to employ a configuration in which the potentials DS of the power-supply lines 32 belonging to the prior pixel row (i.e., the immediately previous row) are supplied as the pulsed voltages V_{sub}, as illustrated in FIG. 18. This configuration can be achieved by connecting the second electrodes of the auxiliary capacitors 25 to the power-supply lines 32 belonging to the prior pixel row.

This is because the high potential of the potential DS of each power-supply line 32 has the voltage value V₁ or larger relative to the source potential of the drive transistor 22 during writing of high-gradation video signals, the low potential of the potential DS of the power-supply line 32 is the second power-supply potential Vᵢₙᵢ, and thus the potential DS of the power-supply line 32 satisfies the above-described condition of the potential of the voltage V_{sub}. In this case, the timing of the voltage V_{sub} applied to the second electrode of the auxiliary capacitor 25 has a deviation of 1H relative to the timing in the case of the second embodiment. However, when the deviation of 1H is set sufficiently small to be ignorable, it is possible to provide substantially the same advantages as those in the case of the second embodiment.

### 3. APPLICATION EXAMPLES

Although an example in which the present disclosure is applied to the pixel circuit having two transistors, i.e., the drive transistor 22 and the write transistor 23, and two capacitance elements, i.e., the storage capacitor 24 and the auxiliary capacitor 25, has been described in the above embodiments, the application of the present disclosure is not limited to the pixel circuit. That is, the present disclosure is applicable to a pixel circuit having a larger number of transistors, a pixel circuit having a larger number of capacitance elements, and so on.

Although an example in which the present disclosure is applied to an organic EL display device has been described in the above embodiments, the application of the present disclosure is not limited thereto. More specifically, the present disclosure is applicable to display devices using current-driven electro-optical elements (light-emitting elements) having emission luminances that vary according to the values of currents flowing devices, such as organic EL elements, LED elements, and semiconductor laser elements. In addition to such display devices using the current-driven electro-optical elements, the present disclosure is applicable to display devices employing a configuration in which capacitance elements are provided in pixels. Examples of such display devices include liquid crystal display devices and plasma display devices.

### 4. ELECTRONIC APPARATUSES

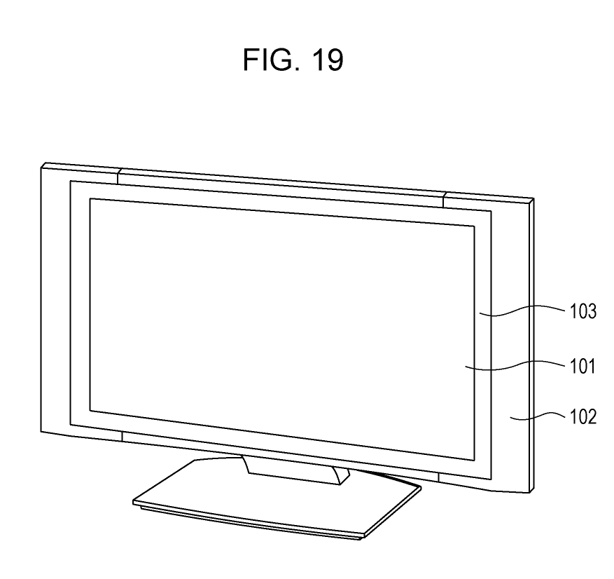

The above-described display device according to the embodiment of the present disclosure is applicable to display units (display devices) for electronic apparatuses in any fields in which video signals input to the electronic apparatuses or video signals generated thereby are displayed in the form of images or video. For example, the present disclosure is applicable to display units for various types of electronic apparatus, such as a television set, a digital camera, a video camera, a notebook personal computer, and a mobile terminal device such as a mobile phone, as illustrated in FIGS. 19 to 23G.

As is apparent from the description of the above embodiments, the display device according to the embodiment of the present disclosure can ensure the reliability of the capacitance elements to be fabricated in the pixels during formation of the capacitance elements between the metal layer and the semiconductor layer, thus making it possible to prevent luminance non-uniformity and luminance reduction. Accordingly, the use of the display device according to the embodiment of the present disclosure as a display unit for an electronic apparatus in an arbitrary field makes it possible to provide a high-quality display image.

The display device according to an embodiment of the present disclosure may also be implemented by a modular form having a sealed structure. The modular form corresponds to, for example, the display module formed by laminating the opposing portions, made of the transparent glass or the like, to the pixel array section. The display module may also be provided with, for example, an FPC (flexible printed circuit) or a circuit section for externally inputting/outputting a signal and so on to/from the pixel array section.

Specific examples of an electronic apparatus to which an embodiment of the present disclosure is applied will be described below.

FIG. 19 is a perspective view illustrating the external appearance of a television set to which an embodiment of the present disclosure is applied. The television set according to the application example includes a video display screen section 101 having a front panel 102, a filter glass 103, and so on. The television set is manufactured by using the display device according to the embodiment of the present disclosure as the video display screen section 101.

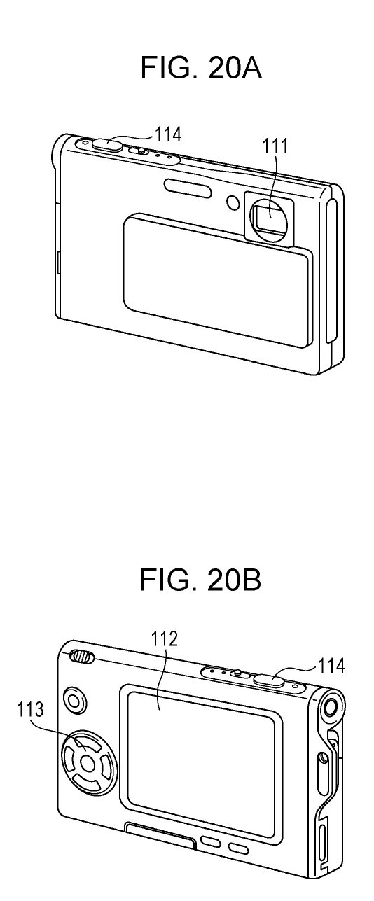

FIGS. 20A and 20B are a front perspective view and a rear perspective view, respectively, illustrating the external appearance of a digital camera to which an embodiment of the present disclosure is applied. The digital camera according to the application example includes a flashlight emitting section 111, a display section 112, a menu switch 113, a shutter button 114, and so on. The digital camera is manufactured using the display device according to the embodiment of the present disclosure as the display section 112.

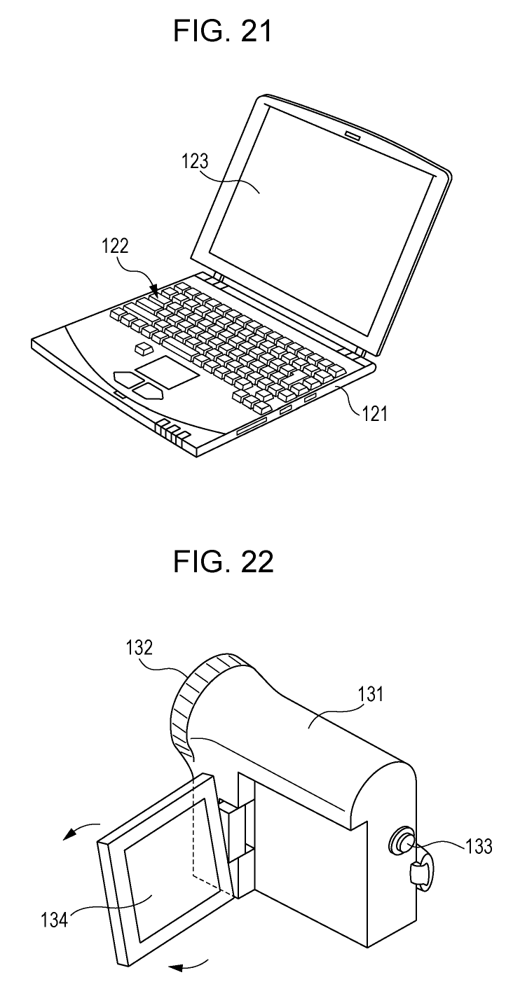

FIG. 21 is a perspective view illustrating the external appearance of a notebook personal computer to which an embodiment of the present disclosure is applied. The notebook personal computer according to the present application example has a configuration in which a main unit 121 includes a keyboard 122 for operation for inputting characters and so on, a display section 123 for displaying an image, and so on. The notebook personal computer is manufactured using the display device according to an embodiment of the present disclosure as the display section 123.

FIG. 22 is a perspective view illustrating the external appearance of a video camera to which an embodiment of the present disclosure is applied. The video camera according to the present application example includes a main unit 131, a subject-shooting lens 132 provided at a front side surface thereof, a start/stop switch 133 for shooting, a display section 134, and so on. The video camera is manufactured using the display device according to an embodiment of the present disclosure as the display section 134.

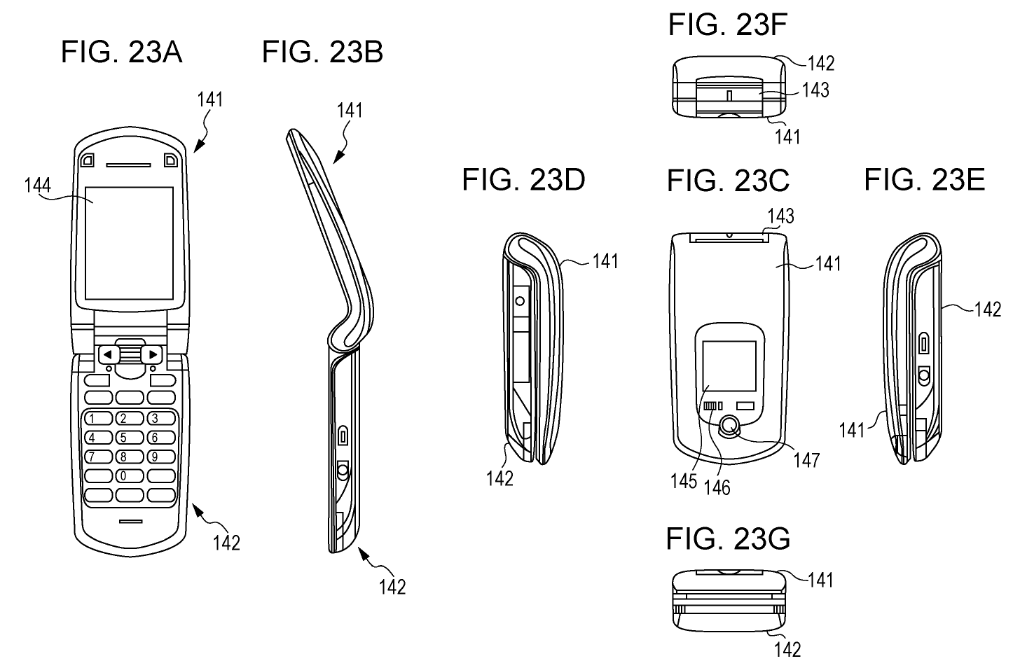

FIGS. 23A to 23G are external views of a mobile terminal device, for example, a mobile phone, to which an embodiment of the present disclosure is applied. Specifically, FIG. 23A is a front view of the mobile phone when it is opened, FIG. 23B is a side view thereof, FIG. 23C is a front view when the mobile phone is closed, FIG. 23D is a left side view, FIG. 23E is a right side view, FIG. 23F is a top view, and FIG. 23G is a bottom view. The mobile phone according to the present application example includes an upper casing 141, a lower casing 142, a coupling portion (a hinge portion, in this case) 143, a display 144, a sub display 145, a picture light 146, a camera 147, and so on. The mobile phone according to the present application example is manufactured using the display device according to the present application example as the display 144 and/or the sub display 145.

### 5. CONFIGURATION OF PRESENT DISCLOSURE

(1) A display device including:

pixels including electro-optical elements and transistors, each pixel having a metal layer of a gate electrode of the transistor, a semiconductor layer in which a source region and a drain region of the transistor are formed, and a capacitance element formed between the same metal layer as the metal layer of the gate electrode and the semiconductor layer upon application of a voltage to the metal layer.

(2) The display device according to (1), wherein the voltage applied to the metal layer is capable of forming a channel at a surface of the semiconductor layer.

(3) The display device according to (2), wherein the voltage applied to the metal layer has a voltage value that is larger than or equal to a voltage value with which C/C₀=1 is satisfied, where C₀ indicates a capacitance of a dielectric between the metal layer and the semiconductor layer and C indicates a capacitance between the metal layer and the semiconductor layer.

(4) The display device according to one of (1) to (3), wherein each capacitance element is used as an auxiliary of an equivalent capacitance of the corresponding electro-optical element.

(5) The display device according to (4), wherein each transistor is connected in series with the corresponding electro-optical element to serve as a drive transistor for driving the electro-optical element; and

each capacitance element has a first electrode connected to a source/drain electrode of the drive transistor.

(6) The display device according to (5), wherein each capacitance element has a second electrode to which a constant voltage is applied as a voltage to be applied to the corresponding metal layer.

(7) The display device according to (6), wherein the pixels are arranged in a matrix to constitute a pixel array section; and

the constant voltage is applied to the second electrodes of the capacitance elements through voltage-supply lines connected to the second elements of the capacitance elements in corresponding rows.

(8) The display device according to (7), wherein the voltage-supply lines connected to the second elements of the capacitance elements in the corresponding rows are bundled together at a peripheral portion of the pixel array section to form a looped common voltage-supply line around the pixel array section; and

the constant voltage is applied to the second electrodes of the capacitance elements through the looped common voltage-supply line and the voltage-supply lines.

(9) The display device according to (8), wherein pads are formed at two opposite ends of a panel at which the pixel array section is provided and are connected to the looped common voltage-supply line; and

the constant voltage is applied to the second electrodes of the capacitance elements through the pads, the looped common voltage-supply line, and the voltage-supply lines.

(10) The display device according to (5), wherein each capacitance element has a second electrode to which a pulsed voltage is applied as a voltage to be applied to the corresponding metal layer.

(11) The display device according to (10), wherein a potential of a power-supply line through which power is supplied to the drive transistor is switchable between a first power-supply potential for supplying current for driving light emission of the electro-optical element and a second power-supply potential for reversely biasing the electro-optical element, and

the pulsed voltage reaches a high potential when the potential of the power-supply line is the first power-supply potential.

(12) The display device according to (11), wherein a low potential of the pulsed voltage is set to the second power-supply potential.

(13) The display device according to one of (10) to (12), wherein the pixels are arranged in a matrix to constitute a pixel array section; and

the pulsed voltage is applied to the second electrodes of the capacitance elements row by row.

(14) The display device according to (13), wherein the pulsed voltage is output from a scan circuit for scanning the pixel array section row by row.

(15) The display device according to (13), wherein the pulsed voltage is supplied through the power-supply line belonging to the prior pixel row.

(16) The display device according to (15), wherein the second electrodes of the capacitance elements are connected to the power-supply line belonging to the prior pixel row.

(17) An electronic apparatus including:

a display device having pixels including electro-optical elements and transistors, each pixel having a metal layer of a gate electrode of the transistor, a semiconductor layer in which a source region and a drain region of the transistor are formed, and a capacitance element formed between the same metal layer as the metal layer of the gate electrode and the semiconductor layer upon application of a voltage to the metal layer.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A display device comprising:
pixels including electro-optical elements and transistors, each pixel having a metal layer of a gate electrode of the transistor, a semiconductor layer in which a source region and a drain region of the transistor are formed, and a capacitance element formed between the same metal layer as the metal layer of the gate electrode and the semiconductor layer upon application of a voltage to the metal layer.

2. The display device according to claim 1, wherein the voltage applied to the metal layer is capable of forming a channel at a surface of the semiconductor layer.

3. The display device according to claim 2, wherein the voltage applied to the metal layer has a voltage value that is larger than or equal to a voltage value with which C/C₀=1 is satisfied, where C₀ indicates a capacitance of a dielectric between the metal layer and the semiconductor layer and C indicates a capacitance between the metal layer and the semiconductor layer.

4. The display device according to claim 1, wherein each capacitance element is used as an auxiliary of an equivalent capacitance of the corresponding electro-optical element.

5. The display device according to claim 4, wherein each transistor is connected in series with the corresponding electro-optical element to serve as a drive transistor for driving the electro-optical element; and
each capacitance element has a first electrode connected to a source/drain electrode of the drive transistor.

6. The display device according to claim 5, wherein each capacitance element has a second electrode to which a constant voltage is applied as a voltage to be applied to the corresponding metal layer.

7. The display device according to claim 6, wherein the pixels are arranged in a matrix to constitute a pixel array section; and
the constant voltage is applied to the second electrodes of the capacitance elements through voltage-supply lines connected to the second elements of the capacitance elements in corresponding rows.

8. The display device according to claim 7, wherein the voltage-supply lines connected to the second elements of the capacitance elements in the corresponding rows are bundled together at a peripheral portion of the pixel array section to form a looped common voltage-supply line around the pixel array section; and
the constant voltage is applied to the second electrodes of the capacitance elements through the looped common voltage-supply line and the voltage-supply lines.

9. The display device according to claim 8, wherein pads are formed at two opposite ends of a panel at which the pixel array section is provided and are connected to the looped common voltage-supply line; and
the constant voltage is applied to the second electrodes of the capacitance elements through the pads, the looped common voltage-supply line, and the voltage-supply lines.

10. The display device according to claim 5, wherein each capacitance element has a second electrode to which a pulsed voltage is applied as a voltage to be applied to the corresponding metal layer.

11. The display device according to claim 10, wherein a potential of a power-supply line through which power is supplied to the drive transistor is switchable between a first power-supply potential for supplying current for driving light emission of the electro-optical element and a second power-supply potential for reversely biasing the electro-optical element, and
the pulsed voltage reaches a high potential when the potential of the power-supply line is the first power-supply potential.

12. The display device according to claim 11, wherein a low potential of the pulsed voltage is set to the second power-supply potential.

13. The display device according to claim 10, wherein the pixels are arranged in a matrix to constitute a pixel array section; and
the pulsed voltage is applied to the second electrodes of the capacitance elements row by row.

14. The display device according to claim 13, wherein the pulsed voltage is output from a scan circuit for scanning the pixel array section row by row.

15. The display device according to claim 13, wherein the pulsed voltage is supplied through the power-supply line belonging to the prior pixel row.

16. The display device according to claim 15, wherein the second electrodes of the capacitance elements are connected to the power-supply line belonging to the prior pixel row.

17. An electronic apparatus comprising:
a display device having pixels including electro-optical elements and transistors, each pixel having a metal layer of a gate electrode of the transistor, a semiconductor layer in which a source region and a drain region of the transistor are formed, and a capacitance element formed between the same metal layer as the metal layer of the gate electrode and the semiconductor layer upon application of a voltage to the metal layer.
